(19) United States
(12) Patent Application Publication
(10) Pub. No.: US 2023/0055630 A1
(43) Pub. Date: Feb. 23, 2023

(54) ORGANIC ELECTROLUMINESCENT MATERIAL AND DEVICE THEREOF

(71) Applicant: BEIJING SUMMER SPROUT TECHNOLOGY CO., LTD., Beijing (CN)

(72) Inventors: Chi Yuen Raymond Kwong, Beijing (CN); Zhen Wang, Beijing (CN); Hongbo Li, Beijing (CN); Ming Sang, Beijing (CN); Zhihong Dai, Beijing (CN); Nannan Lu, Beijing (CN); Qi Zhang, Beijing (CN); Wei Cai, Beijing (CN); Zheng Wang, Beijing (CN); Cuifang Zhang, Beijing (CN); Qi Liu, Beijing (CN); Menglan Xie, Beijing (CN); Chuanjun Xia, Beijing (CN)

(73) Assignee: BEIJING SUMMER SPROUT TECHNOLOGY CO., LTD., Beijing (CN)

(21) Appl. No.: 17/859,914

(22) Filed: Jul. 7, 2022

(30) Foreign Application Priority Data
Jul. 9, 2021 (CN) 202110773083.8

(51) Int. Cl. C07F 15/00; H01L 51/50; H01L 51/00

(52) U.S. Cl. CPC C07F 15/0033; C07F 15/0086; H01L 51/5036; H01L 51/0085; H01L 51/0087; C07B 2200/05

(57) ABSTRACT

Provided are an organic electroluminescent material and a device thereof. The organic electroluminescent material includes a metal M and at least one C\hat{ }N bidentate ligand Lₐ coordinated with the metal M, the maximum emission wavelength of the photoluminescence spectrum of the organic electroluminescent material at room temperature is greater than or equal to 410 nm and less than or equal to 700 nm, and the emission spectrum area ratio of the organic electroluminescent material is less than or equal to 0.145. The metal complex has significant advantages in organic electroluminescent devices, in particular the improvement of device efficiency. Further provided are an organic electroluminescent device including the metal complex and a compound composition including the metal complex.

### CROSS-REFERENCE TO RELATED APPLICATION(S)

This application claims priority to Chinese Patent Application No. 202110773083.8 filed on Jul. 9, 2021, the disclosure of which is incorporated herein by reference in its entirety.

### TECHNICAL FIELD

The present disclosure relates to compounds for organic electronic devices, for example, an organic light-emitting device. More in particular, the present disclosure relates to a metal complex. The metal complex includes a metal M and at least one C\hat{ }N bidentate ligand Lₐ coordinated with the metal M, the maximum emission wavelength of the photoluminescence spectrum of the metal complex at room temperature is greater than or equal to 410 nm and less than or equal to 700 nm, and the emission spectrum area ratio of the metal complex is less than or equal to 0.145. The present disclosure further relates to an organic electroluminescent device including the metal complex and a compound composition including the metal complex.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which includes an arylamine hole transporting layer and a tris-8-hydroxyquinolato-aluminum layer as the electron and emitting layer (Applied Physics Letters, 1987, 51 (12): 913-915). Once a bias is applied to the device, green light was emitted from the device. This device laid the foundation for the development of modern organic light-emitting diodes (OLEDs). State-of-the-art OLEDs may include multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation. Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may include one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

The luminous efficiency of the OLED is an important parameter to evaluate the properties of OLED luminescent materials. At present, besides the published or reported manner of predicting the efficiency of OLED luminescent materials with the same or similar skeletons by comparing the length of transition dipole moments of OLED luminescent materials with the same or similar skeletons, there is no more effective method to judge the luminescent efficiency of OLED devices through the simple physical properties of OLED luminescent materials.

### SUMMARY

The present application discloses a metal complex having an emission spectrum area ratio less than 0.145, and such a metal complex has a higher device efficiency than a metal complex having an emission spectrum area ratio greater than 0.145. According to the research of the inventors of the present application, as far as the emission spectrum of a single luminescent material is concerned, the smaller the emission spectrum area ratio is, the more concentrated the energy distribution of photons is, which is beneficial to enable the device to have a higher emission efficiency.

According to an embodiment of the present disclosure, a metal complex is disclosed, wherein the maximum emission wavelength of the photoluminescence spectrum of the metal complex at room temperature is greater than or equal to 410 nm and less than or equal to 700 nm;

when the maximum emission wavelength is λ₁ and λ₁ is greater than or equal to 410 nm and less than 500 nm, the emission spectrum area ratio of the metal complex is AR1, and AR1 is less than or equal to 0.145;

when the maximum emission wavelength is λ₂ and λ₂ is greater than or equal to 500 nm and less than 580 nm, the emission spectrum area ratio of the metal complex is AR2, and AR2 is less than or equal to 0.145;

when the maximum emission wavelength is λ₃ and λ₃ is greater than or equal to 580 nm and less than or equal to 700 nm, the emission spectrum area ratio of the metal complex is AR3, and AR3 is less than or equal to 0.145;

the emission intensity of the metal complex is less than or equal to 0.2 at wavelengths of 380 nm and 780 nm;

the metal complex comprises a metal M and at least one C\hat{ }N bidentate ligand Lₐ coordinated with the metal M;

the metal M is selected from metals having a relative atomic mass greater than 40;

the ligand Lₐ at least comprises ring A and B, which are directly linked;

the ring A is, at each occurrence identically or differently, selected from a substituted or unsubstituted heteroaromatic ring having 5 to 6 ring atoms;

the ring B is, at each occurrence identically or differently, selected from a substituted or unsubstituted benzene ring or a substituted or unsubstituted heteroaromatic ring having 5 to 6 ring atoms;

the ring A is linked to the metal through a metal-nitrogen bond;

the ring B is linked to the metal through a metal-carbon bond;

adjacent substituents in rings A and B can be optionally joined to form a ring.

According to another embodiment of the present disclosure, an electroluminescent device is further disclosed, which includes an anode, a cathode and an organic layer disposed between the anode and the cathode, where at least one layer of the organic layer includes the metal complex described in the preceding embodiments.

According to another embodiment of the present disclosure, a compound composition is further disclosed, which includes the metal complex described in the preceding embodiments.

The present disclosure discloses a metal complex. The metal complex includes a metal M and at least one C\hat{ }N bidentate ligand Lₐ coordinated with the metal M, the emission intensity of the metal complex is less than or equal to 0.2 at wavelengths of 380 nm and 780 nm, the maximum emission wavelength of the photoluminescence spectrum of the metal complex at room temperature is greater than or equal to 410 nm and less than or equal to 700 nm, and the emission spectrum area ratio of the metal complex is less than or equal to 0.145. Such new compounds are applicable to electroluminescent devices and can provide excellent device performance, especially the improvement of device efficiency.

### BRIEF DESCRIPTION OF DRAWINGS

FIG. 1 is a schematic diagram of an organic light-emitting device that may include a metal complex and a compound composition disclosed herein.

FIG. 2 is a schematic diagram of another organic light-emitting device that may include a metal complex and a compound composition disclosed herein.

FIG. 3 is a normalized photoluminescence spectrogram.

### DETAILED DESCRIPTION

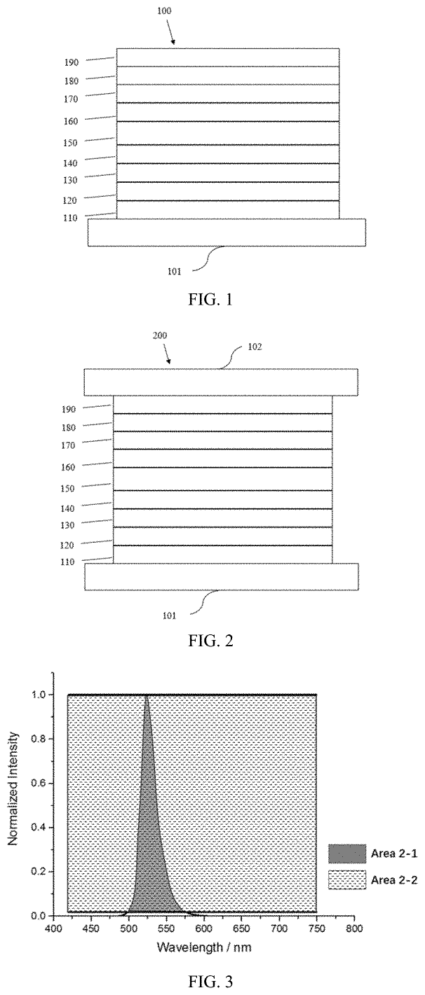

OLEDs can be fabricated on various types of substrates such as glass, plastic, and metal foil. FIG. 1 schematically shows an organic light-emitting device 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may include a single layer or multiple layers.

An OLED can be encapsulated by a barrier layer. FIG. 2 schematically shows an organic light emitting device 200 without limitation. FIG. 2 differs from FIG. 1 in that the organic light emitting device include a barrier layer 102, which is above the cathode 190, to protect it from harmful species from the environment such as moisture and oxygen. Any material that can provide the barrier function can be used as the barrier layer such as glass or organic-inorganic hybrid layers. The barrier layer should be placed directly or indirectly outside of the OLED device. Multilayer thin film encapsulation was described in U.S. Pat. No. 7,968,146, which is incorporated by reference herein in its entirety.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (ΔE_{S-T}). Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in small ΔE_{S-T}. These states may involve CT states. Generally, donor-acceptor luminescent materials are constructed by connecting an electron donor moiety such as amino- or carbazole-derivatives and an electron acceptor moiety such as N-containing six-membered aromatic rings.

### Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, an n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, a n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylethylgermanylmethyl, dimethylisopropylgermanylmethyl, tert-butylmethylgermanylmethyl, triethylgermanylmethyl, triethylgermanylethyl, triisopropylgermanylmethyl, triisopropylgermanylethyl, trimethylsilylmethyl, trimethylsilylethyl, and trimethylsilylisopropyl, triisopropylsilylmethyl, triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups or heterocycle—as used herein include non-aromatic cyclic groups. Non-aromatic heterocyclic groups include saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms.

Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with an aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl—as used herein contemplates a germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzo[f,h]quinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, amino, acyl, carbonyl, a carboxylic acid group, an ester group, sulfinyl, sulfonyl, and phosphino may be substituted with one or more moieties selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl group having 6 to 20 carbon atoms, unsubstituted alkylgermanyl having 3 to 20 carbon atoms, unsubstituted arylgermanyl having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen may also be replaced by their other stable isotopes. The replacement by other stable isotopes in the compounds may be preferred due to its enhancements of device efficiency and stability.

In the compounds mentioned in the present disclosure, multiple substitution refers to a range that includes a di-substitution, up to the maximum available substitution. When substitution in the compounds mentioned in the present disclosure represents multiple substitution (including di-, tri-, and tetra-substitutions etc.), that means the substituent may exist at a plurality of available substitution positions on its linking structure, the substituents present at a plurality of available substitution positions may have the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fusedcyclic, and etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

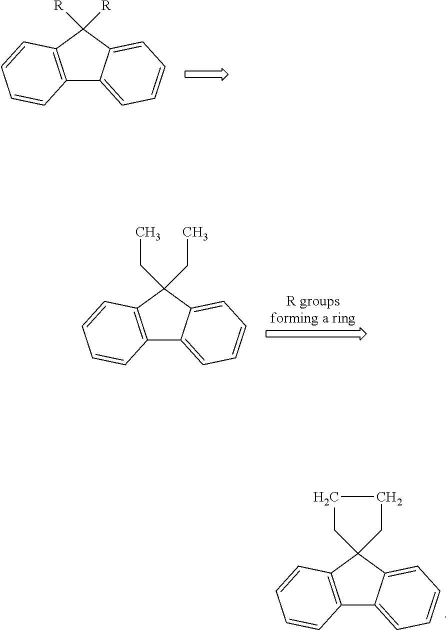

The expression that adjacent substituents can be optionally joined to form a ring is also intended to mean that two substituents bonded to carbon atoms which are directly bonded to each other are joined to each other via a chemical bond to form a ring, which can be exemplified by the following formula:

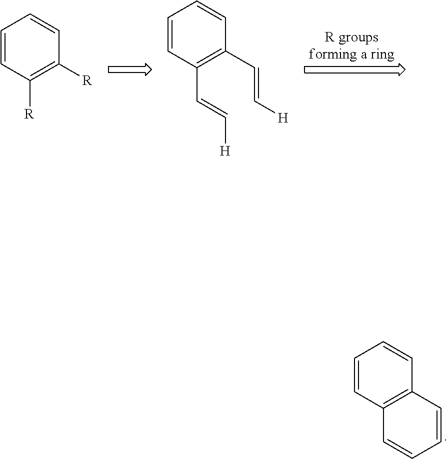

The expression that adjacent substituents can be optionally joined to form a ring is also intended to mean that two substituents bonded to a further distant carbon atom are joined to each other via a chemical bond to form a ring, which can be exemplified by the following formula:

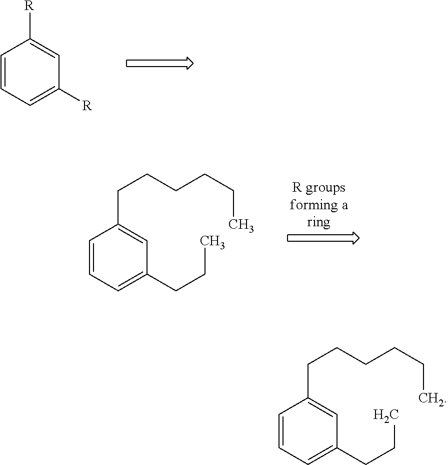

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula:

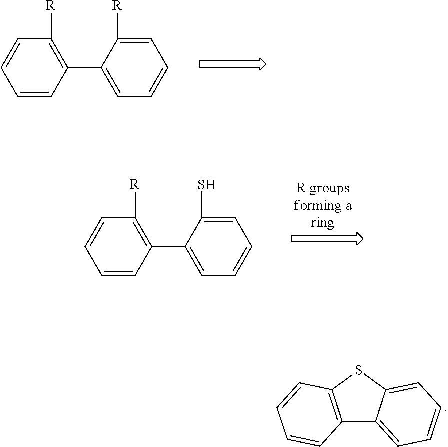

According to an embodiment of the present disclosure, a metal complex is disclosed, wherein the maximum emission wavelength of the photoluminescence spectrum of the metal complex at room temperature is greater than or equal to 410 nm and less than or equal to 700 nm;

when the maximum emission wavelength is λ₁ and λ₁ is greater than or equal to 410 nm and less than 500 nm, the emission spectrum area ratio of the metal complex is AR1, and AR1 is less than or equal to 0.145;

when the maximum emission wavelength is λ₂ and λ₂ is greater than or equal to 500 nm and less than 580 nm, the emission spectrum area ratio of the metal complex is AR2, and AR2 is less than or equal to 0.145;

when the maximum emission wavelength is λ₃ and λ₃ is greater than or equal to 580 nm and less than or equal to 700 nm, the emission spectrum area ratio of the metal complex is AR3, and AR3 is less than or equal to 0.145;

the emission intensity of the metal complex is less than or equal to 0.2 at wavelengths of 380 nm and 780 nm;

the metal complex comprises a metal M and at least one C\hat{ }N bidentate ligand Lₐ coordinated with the metal M;

the metal M is selected from metals having a relative atomic mass greater than 40; the ligand Lₐ at least comprises ring A and B, which are directly linked;

the ring A is, at each occurrence identically or differently, selected from a substituted or unsubstituted heteroaromatic ring having 5 to 6 ring atoms;

the ring B is, at each occurrence identically or differently, selected from a substituted or unsubstituted benzene ring or a substituted or unsubstituted heteroaromatic ring having 5 to 6 ring atoms;

the ring A is linked to the metal through a metal-nitrogen bond;

the ring B is linked to the metal through a metal-carbon bond;

adjacent substituents in rings A and B can be optionally joined to form a ring.

In the present disclosure, the expression that “the emission intensity of the metal complex is less than or equal to 0.2 at wavelengths of 380 nm and 780 nm” means that when the metal complex is prepared into a toluene solution at a concentration of 1×10⁻⁶ mol/L, measured the photoluminescence spectrum of the toluene solution at room temperature (298 K) and then normalized, the mission intensity is less than or equal to 0.2 at wavelengths of 380 nm and 780 nm.

In this embodiment, the expression that “adjacent substituents in rings A and B can be optionally joined to form a ring” is intended to mean that any one or more of groups of adjacent substituents, such as two adjacent substituents in the ring A, two adjacent substituents in the ring B and adjacent substituents in the rings A and B, can be joined to form a ring. Obviously, it is possible that none of these substituents are joined to form a ring.

According to an embodiment of the present disclosure, wherein, the maximum emission wavelength λ₁ of the metal complex at room temperature is greater than or equal to 420 and less than or equal to 480 nm, the maximum emission wavelength λ₂ is greater than or equal to 500 nm and less than or equal to 560 nm, and the maximum emission wavelength λ₃ is greater than or equal to 580 nm and less than or equal to 650 nm.

According to an embodiment of the present disclosure, wherein, the maximum emission wavelength λ₁ of the metal complex at room temperature is greater than or equal to 440 nm and less than or equal to 470 nm, the maximum emission wavelength λ₂ is greater than or equal to 500 nm and less than or equal to 540 nm, and the maximum emission wavelength λ₃ is greater than or equal to 600 nm and less than or equal to 640 nm.

According to an embodiment of the present disclosure, wherein, AR2 of the metal complex is less than or equal to 0.140.

According to an embodiment of the present disclosure, wherein, AR2 of the metal complex is less than or equal to 0.138.

According to an embodiment of the present disclosure, wherein, AR2 of the metal complex is less than or equal to 0.135.

According to an embodiment of the present disclosure, wherein, AR2 of the metal complex is less than or equal to 0.088.

According to an embodiment of the present disclosure, wherein, AR3 of the metal complex is less than or equal to 0.130.

According to an embodiment of the present disclosure, wherein, AR3 of the metal complex is less than or equal to 0.120.

According to an embodiment of the present disclosure, wherein, AR3 of the metal complex is less than or equal to 0.110.

According to an embodiment of the present disclosure, wherein, AR3 of the metal complex is less than or equal to 0.088.

According to an embodiment of the present disclosure, wherein, the metal M is, at each occurrence identically or differently, selected from the group consisting of Cu, Ag, Au, Ru, Rh, Pd, Os, Ir, and Pt.

According to an embodiment of the present disclosure, wherein, the metal M is, at each occurrence identically or differently, selected from Pt or Ir.

According to an embodiment of the present disclosure, wherein, the metal complex has a structure represented by Formula I or Formula II:

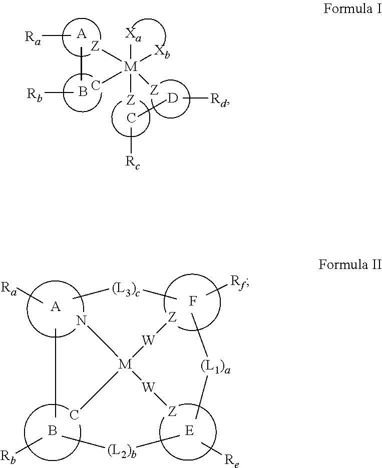

wherein

the metal M is selected from metals having a relative atomic mass greater than 40;

ligand C-D is identical to or different from ligand A-B;

ligand E-(L₁)ₐ-F is identical to or different from ligand A-B;

ligand

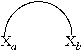

represents a monoanionic bidentate ligand and is identical to or different from ligand A-B;

the ring A is selected from a substituted or unsubstituted heteroaromatic ring having 5 to 6 ring atoms;

the ring B is selected from a substituted or unsubstituted benzene ring or a substituted or unsubstituted heteroaromatic ring having 6 ring atoms;

ring C, ring D, ring E, and ring F are, at each occurrence identically or differently, selected from an aromatic ring having 6 to 30 carbon atoms, a heteroaromatic ring having 3 to 30 carbon atoms or combinations thereof;

Z is, at each occurrence identically or differently, selected from C or N;

W is, at each occurrence identically or differently, selected from a single bond, O, S, Se, NR′, CR′R′ and SiR′R′; when two R′ are present at the same time, the two R′ are identical or different;

Xₐ and X_{b} are, at each occurrence identically or differently, selected from C, N, O, S or Se;

L₁, L₂, and L₃ are, at each occurrence identically or differently, selected from the group consisting of: a single bond, BR₁, CRIR₁, NR₁, SiRIR₁, PR₁, GeR₁R₁, O, S, Se, substituted or unsubstituted vinylene, ethynylene, substituted or unsubstituted arylene having 5 to 30 carbon atoms, substituted or unsubstituted heteroarylene having 5 to 30 carbon atoms, and combinations thereof; when two R₁ are present at the same time, the two R₁ are identical or different;

a, b, and c are, at each occurrence identically or differently, selected from 0 or 1;

Rₐ, R_{b}, R_{c}, R_{d}, Rₑ, and R_{f} represent, at each occurrence identically or differently, mono-substitution, multiple substitutions or non-substitution;

R′, Rₐ, R_{b}, R_{c}, R_{d}, Rₑ, R_{f}, and R₁ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

adjacent substituents R′, Rₐ, R_{b}, R_{c}, R_{d}, Rₑ, R_{f}, and R₁ can be optionally joined to form a ring.

In the present disclosure, the expression that “adjacent substituents R′, Rₐ, R_{b}, R_{c}, R_{d}, Rₑ, R_{f}, and R₁ can be optionally joined to form a ring” is intended to mean that any one or more of groups of adjacent substituents, such as two substituents R′, two substituents R₁, two substituents Rₐ, two substituents R_{b}, two substituents R_{c}, two substituents R_{d}, two substituents Rₑ, two substituents R_{f}, substituents Rₐ and R_{b}, substituents R_{b} and R_{c}, substituents R_{c} and R_{d}, substituents R₁ and Rₐ, substituents R₁ and R_{b}, substituents R₁ and Rₑ, substituents R₁ and R_{f}, and substituents R′ and R₁, can be joined to form a ring. Obviously, it is possible that none of these substituents are joined to form a ring.

According to an embodiment of the present disclosure, wherein, at least one of Rₐ and/or at least one of R_{b} are selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

According to an embodiment of the present disclosure, wherein, the ligand La (ligand A-B) is, at each occurrence identically or differently, selected from structures represented by Formula 1 and/or Formula 2:

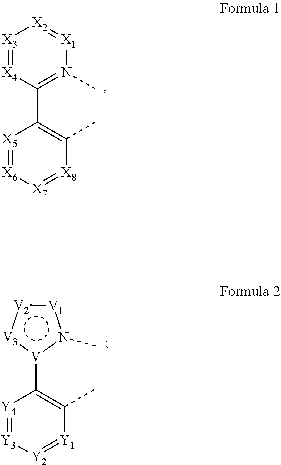

wherein

V is, at each occurrence identically or differently, selected from C or N;

V₁ to V₃ are, at each occurrence identically or differently, selected from O, S, N, CRᵥ or NRᵥ;

X₁ to X₈ are, at each occurrence identically or differently, selected from CRₓ or N;

Y₁ to Y₄ are, at each occurrence identically or differently, selected from CR_{y} or N;

Rᵥ, Rₓ, and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

adjacent substituents in Formula 1 can be optionally joined to form a ring;

adjacent substituents in Formula 2 can be optionally joined to form a ring.

In the present disclosure, the expression that “adjacent substituents in Formula 1 can be optionally joined to form a ring” is intended to mean that any one or more of groups of adjacent substituents in Formula 1, such as any two substituents Rₓ, can be joined to form a ring. Obviously, it is possible that none of these substituents are joined to form a ring.

In the present disclosure, the expression that “adjacent substituents in Formula 2 can be optionally joined to form a ring” is intended to mean that any one or more of groups of adjacent substituents in Formula 2, such as two substituents R_{y}, two substituents Rᵥ, and adjacent substituents Rᵥ and R_{y}, can be joined to form a ring. Obviously, it is possible that none of these substituents are joined to form a ring.

According to an embodiment of the present disclosure, wherein, La (ligand A-B) has, at each occurrence identically or differently, a structure represented by Formula 3, Formula 4 or Formula 5:

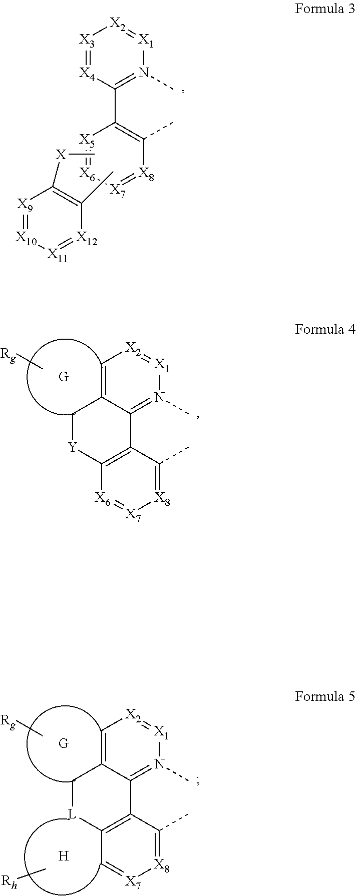

wherein

ring G is, at each occurrence identically or differently, selected from a five-membered unsaturated carbocyclic ring, an aromatic ring having 6 to 30 carbon atoms or a heteroaromatic ring having 3 to 30 carbon atoms;

ring H is, at each occurrence identically or differently, selected from a heterocyclic ring having 2 to 30 carbon atoms or a heteroaromatic ring having 2 to 30 carbon atoms;

R_{g} and Rₕ represent, at each occurrence identically or differently, mono-substitution, multiple substitutions or non-substitution;

X is selected from the group consisting of O, S, Se, NR₂, CR₂R₂, and SiR₂R₂, and when two R₂ are present at the same time, the two R₂ may be identical or different;

Y is selected from the group consisting of O, S, Se, SiR₃R₃, GeR₃R₃, NR₃, and PR₃, and when two R₃ are present at the same time, the two R₃ may be identical or different;

L is, at each occurrence identically or differently, selected from B, N or P;

X₁ to X₁₂ are, at each occurrence identically or differently, selected from C, CRₓ or N;

R₂, R₃, Rₓ, R_{g}, and Rₕ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

adjacent substituents in Formula 3 can be optionally joined to form a ring;

adjacent substituents in Formula 4 can be optionally joined to form a ring;

adjacent substituents in Formula 5 can be optionally joined to form a ring.

In the present disclosure, the expression that “adjacent substituents in Formula 3 can be optionally joined to form a ring” is intended to mean that any one or more of groups of adjacent substituents in Formula 3, such as two substituents Rₓ and adjacent substituents R₂ and Rₓ, can be joined to form a ring. Obviously, it is possible that none of these substituents are joined to form a ring.

In the present disclosure, the expression that “adjacent substituents in Formula 4 can be optionally joined to form a ring” is intended to mean that any one or more of groups of adjacent substituents in Formula 4, such as two substituents Rₓ, two substituents R_{g}, two substituents R₃, adjacent substituents R₃ and Rₓ, adjacent substituents R₃ and R_{g}, and adjacent substituents R_{g} and Rₓ, can be joined to form a ring. Obviously, it is possible that none of these substituents are joined to form a ring.

In the present disclosure, the expression that “adjacent substituents in Formula 5 can be optionally joined to form a ring” is intended to mean that any one or more of groups of adjacent substituents in Formula 5, such as two substituents Rₓ, two substituents R_{g}, two substituents Rₕ, adjacent substituents Rₕ and Rₓ, and adjacent substituents R_{g} and Rₓ, can be joined to form a ring. Obviously, it is possible that none of these substituents are joined to form a ring.

According to an embodiment of the present disclosure, wherein, the ligand A-B has a structure represented by Formula 4-1:

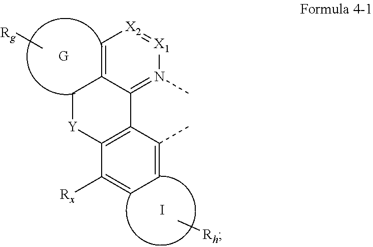

wherein ring G and ring I are, at each occurrence identically or differently, selected from a five-membered unsaturated carbocyclic ring, an aromatic ring having 6 to 30 carbon atoms or a heteroaromatic ring having 3 to 30 carbon atoms;

Y is selected from the group consisting of O, S, Se, SiR₃R₃, GeR₃R₃, NR₃, and PR₃, and when two R₃ are present at the same time, the two R₃ may be identical or different;

X₁ and X₂ are, at each occurrence identically or differently, selected from CRₓ or N;

R_{g} and Rₕ represent, at each occurrence identically or differently, mono-substitution, multiple substitutions or non-substitution;

R_{g}, Rₕ, R₃, and Rₓ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, hydroxyl group, a sulfanyl group, a sulfinyl group, a sulfonyl group, a phosphino group, and combinations thereof;

adjacent substituents R_{g}, Rₕ, R₃ and Rₓ in Formula 4-1 can be optionally joined to form a ring.

In this embodiment, the expression that “adjacent substituents R_{g}, Rₕ, R₃, and Rₓ in Formula 4-1 can be optionally joined to form a ring” is intended to mean that any one or more of groups of adjacent substituents in Formula 4-1, such as two substituents Rₓ, two substituents R_{g}, two substituents Rₕ, two substituents R₃, adjacent substituents Rₕ and Rₓ, adjacent substituents R₃ and Rₓ, and adjacent substituents R₃ and R_{g}, can be joined to form a ring. Obviously, it is possible that none of these substituents are joined to form a ring.

According to an embodiment of the present disclosure, wherein, the ligand A-B is, at each occurrence identically or differently, selected from a group consisting of the following structures:

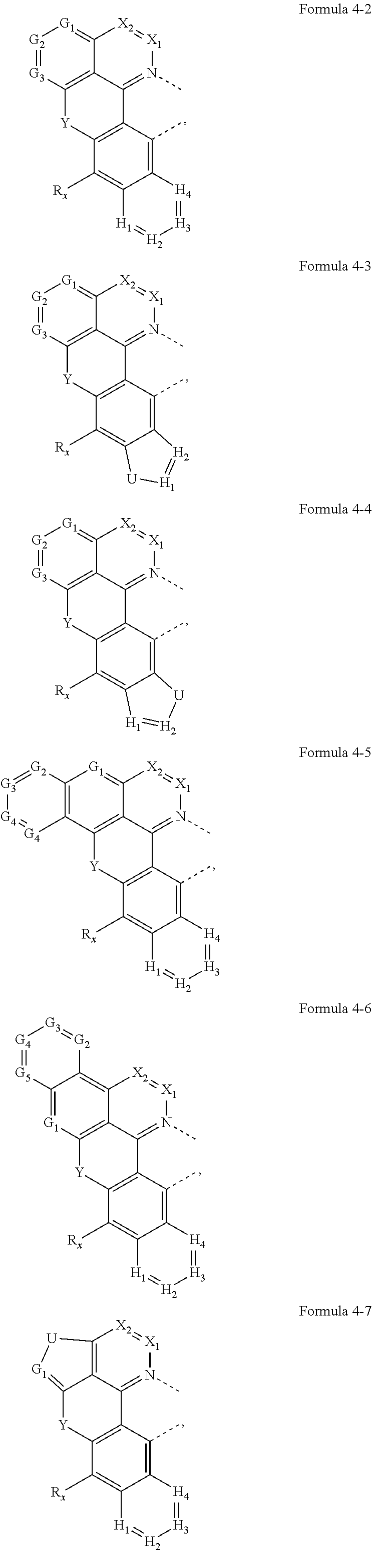

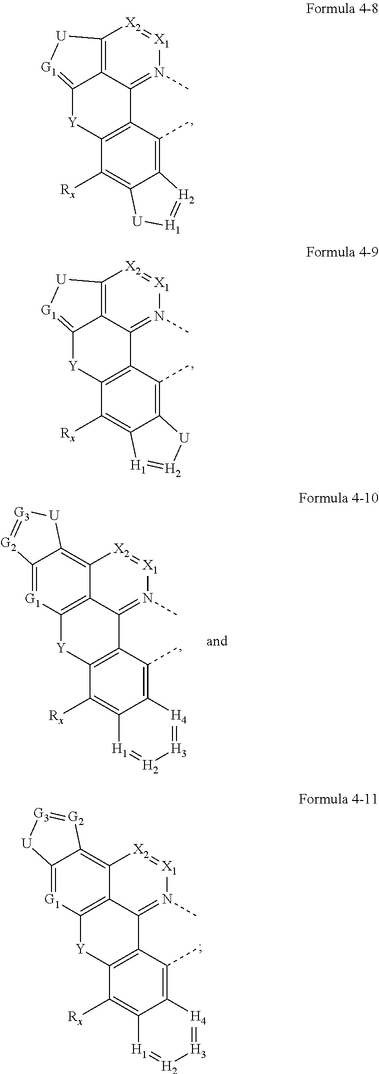

wherein

Y is selected from the group consisting of O, S, Se, SiR₃R₃, GeR₃R₃, NR₃, and PR₃, and when two R₃ are present at the same time, the two R₃ may be identical or different; U is, at each occurrence identically or differently, selected from O, S, Se, CRᵤRᵤ, SiRᵤRᵤ, PRᵤ or NRᵤ; when two Rᵤ are present at the same time, the two Rᵤ are identical or different;

G₁ to G₅ are, at each occurrence identically or differently, selected from CR_{g} or N;

H₁ to H₄ are, at each occurrence identically or differently, selected from CRₕ or N;

R₃, Rₓ, R_{g}, Rₕ, and Rᵤ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, hydroxyl group, a sulfanyl group, a sulfinyl group, a sulfonyl group, a phosphino group, and combinations thereof;

adjacent substituents R₃, Rₓ, R_{g}, Rₕ, and Rᵤ in Formula 4-2 to Formula 4-11 can be optionally joined to form a ring.

In this embodiment, the expression that “adjacent substituents R₃, Rₓ, R_{g}, Rₕ, and Rᵤ in Formula 4-2 to Formula 4-11 can be optionally joined to form a ring” is intended to mean that any one or more of groups of adjacent substituents in Formula 4-2 to Formula 4-11, such as two substituents Rₓ, two substituents R_{g}, two substituents Rₕ, two substituents Rᵤ, two substituents R₃, adjacent substituents Rₕ and Rₓ, adjacent substituents R₃ and Rₓ, adjacent substituents R₃ and R_{g}, and adjacent substituents Rᵤ and R_{g}, can be joined to form a ring. Obviously, it is possible that none of these substituents are joined to form a ring.

According to an embodiment of the present disclosure, wherein, the ligand A-B is selected from a structure represented by Formula 4-2 or Formula 4-7.

According to an embodiment of the present disclosure, wherein, ring G, ring H, and ring I are, at each occurrence identically or differently, selected from an aromatic ring having 6 to 18 carbon atoms or a heteroaromatic ring having 3 to 18 carbon atoms, and ring B is selected from a heteroaromatic ring having 2 to 18 carbon atoms.

According to an embodiment of the present disclosure, wherein, ring G, ring H, and ring I are, at each occurrence identically or differently, selected from a benzene ring, a naphthalene ring, a pyridine ring, a pyrimidine ring, a pyrazine ring, azanaphthalene ring, a furan ring, a thiophene ring, an isoxazole ring, an isothiazole ring, a pyrrole ring, a pyrazole ring, a benzofuran ring, a benzothiophene ring, an azabenzofuran ring or an azabenzothiophene ring; and ring E is selected from a pyrrole ring, an indole ring, an imidazole ring, a pyrazole ring, a triazole ring or an azaindole ring.

According to an embodiment of the present disclosure, wherein, ring G, ring H, and ring I are, at each occurrence identically or differently, selected from a benzene ring, a naphthalene ring, a pyridine ring or a pyrimidine ring, and ring E is selected from a pyrrole ring, an indole ring or an azaindole ring.

According to an embodiment of the present disclosure, wherein, the ligand A-B is, at each occurrence identically or differently, selected from a group consisting of the following structures:

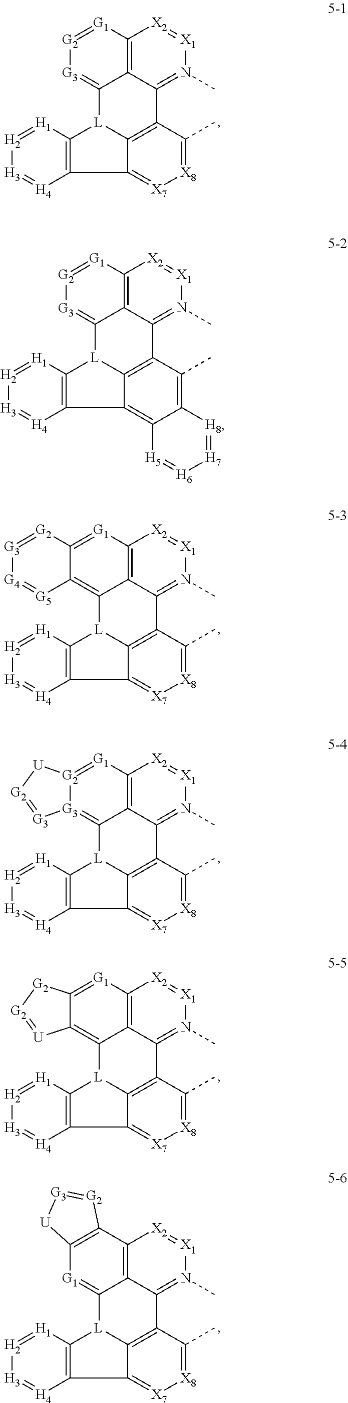

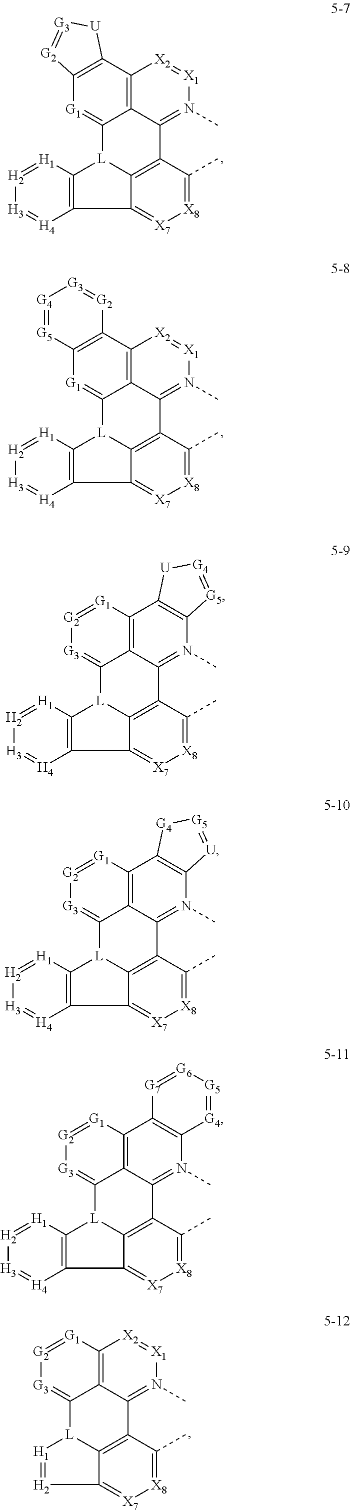

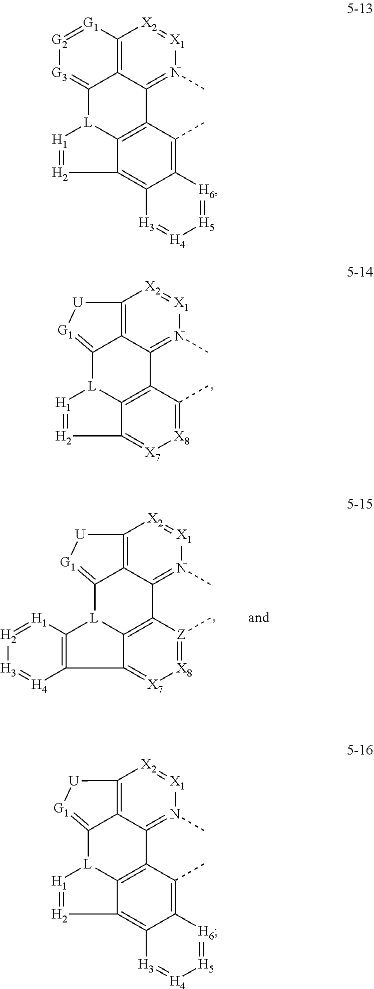

wherein

L is, at each occurrence identically or differently, selected from B, N or P;

X₁, X₂, X₇, and X₈ are, at each occurrence identically or differently, selected from N or CRₓ;

G₁ to G7 are, at each occurrence identically or differently, selected from CR₉ or N;

H₁ to H₈ are, at each occurrence identically or differently, selected from CRₕ or N;

U is, at each occurrence identically or differently, selected from O, S, Se, CRᵤRᵤ, SiRᵤRᵤ, PRᵤ or NRᵤ; when two Rᵤ are present at the same time, the two Rᵤ are identical or different;

Rₓ, R_{g}, Rₕ, and Rᵤ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

adjacent substituents Rₓ, R_{g}, Rₕ, and Rᵤ can be optionally joined to form a ring.

In this embodiment, the expression that “adjacent substituents Rₓ, R_{g}, Rₕ, and Rᵤ can be optionally joined to form a ring” is intended to mean that any one or more of groups of adjacent substituents, such as two substituents Rₓ, two substituents R_{g}, two substituents Rₕ, two substituents Rᵤ, adjacent substituents Rᵤ and Rₓ, and adjacent substituents Rᵤ and R_{g}, can be joined to form a ring. Obviously, it is possible that none of these substituents are joined to form a ring.

According to an embodiment of the present disclosure, wherein, the ligand A-B is selected from a structure represented by Formula 5-1, Formula 5-2, Formula 5-6, Formula 5-7, Formula 5-8 or Formula 5-11.

According to an embodiment of the present disclosure, wherein, the ligand A-B is selected from a structure represented by Formula 5-1, Formula 5-2 or Formula 5-11.

According to an embodiment of the present disclosure, wherein, the ligand E-(L₁)ₐ-F is, at each occurrence identically or differently, selected from the group consisting of the following structures:

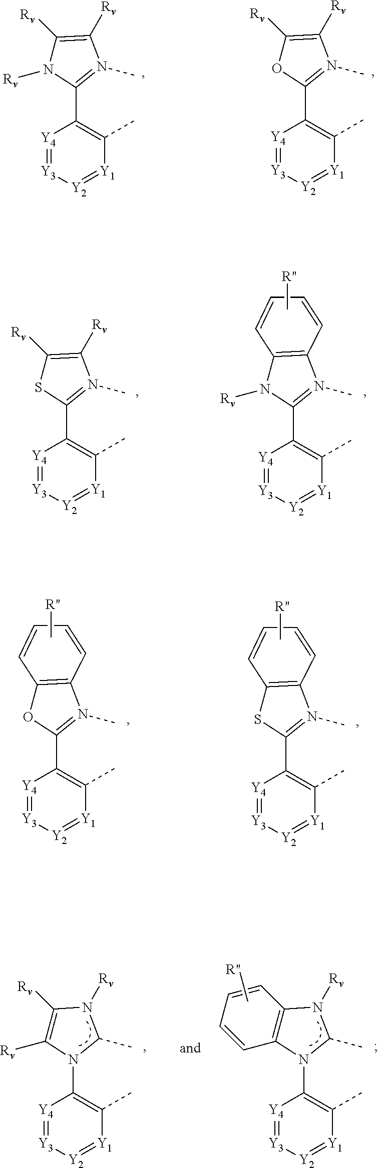

wherein

Y₁ to Y₄ are, at each occurrence identically or differently, selected from CR_{y} or N;

R″ represents, at each occurrence identically or differently, mono-substitution, multiple substitutions or non-substitution;

R″, Rᵥ, and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

adjacent substituents R″, Rᵥ, and R_{y} can be optionally joined to form a ring.

In this embodiment, the expression that “adjacent substituents R″, Rᵥ, and R_{y} can be optionally joined to form a ring” is intended to mean that any one or more of groups of adjacent substituents, such as two substituents R″, two substituents Rᵥ, two substituents R_{y}, and adjacent substituents Rᵥ and R″, can be joined to form a ring. Obviously, it is possible that none of these substituents are joined to form a ring.

According to an embodiment of the present disclosure, wherein, the ligand

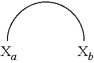

is, at each occurrence identically or differently, selected from the group consisting of Formula a to Formula m, the ligand C-D is, at each occurrence identically or differently, selected from the group consisting of Formula a to Formula h, and the ligand E-(L₁)ₐ-F is, at each occurrence identically or differently, selected from the group consisting of Formula a to Formula 1:

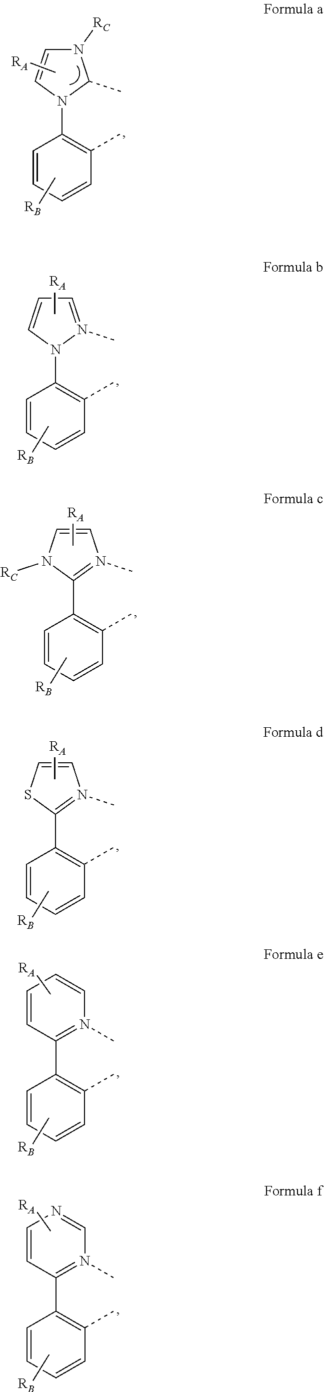

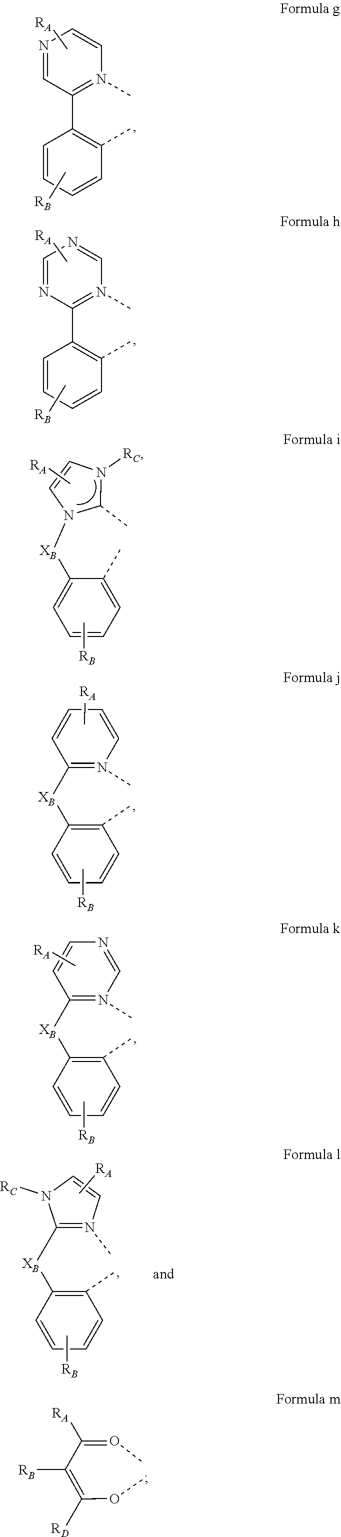

wherein

R_{A} and R_{B} represent, at each occurrence identically or differently, mono-substitution, multiple substitutions or non-substitution;

X_{B} is, at each occurrence identically or differently, selected from the group consisting of: O, S, Se, NR_{N1}, and CR_{C1}R_{C2};

R_{A}, R_{B}, R_{C}, R_{D}, R_{N1}, R_{C1}, and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

adjacent substituents R_{A}, R_{B}, R_{C}, R_{D}, R_{N1}, R_{C1}, and R_{C2} can be optionally joined to form a ring.

In this embodiment, the expression that “adjacent substituents R_{A}, R_{B}, R_{C}, R_{D}, R_{N1}, R_{C1}, and R_{C2} can be optionally joined to form a ring” is intended to mean that any one or more of groups of adjacent substituents, such as two substituents R_{A}, two substituents R_{B}, substituents R_{A} and R_{B}, substituents R_{A} and R_{C}, substituents R_{B} and R_{C}, substituents R_{A} and R_{N1}, substituents R_{B} and R_{N1}, substituents R_{A} and R_{C1}, substituents R_{A} and R_{C2}, substituents R_{B} and R_{C1}, substituents R_{B} and R_{C2}, and substituents R_{C1} and R_{C2}, can be joined to form a ring. Obviously, it is possible that none of these substituents are joined to form a ring.

According to an embodiment of the present disclosure, wherein, the metal complex has a structure represented by Formula 6, Formula 7, Formula 8 or Formula 9:

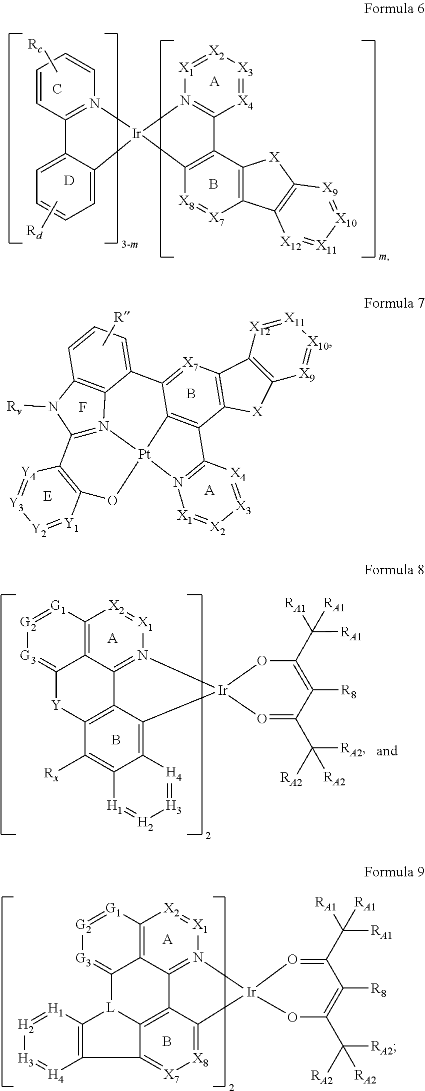

wherein

m is selected from 1, 2 or 3; when m is selected from 1, the ligand C-D is identical or different; when m is selected from 2 or 3, a plurality of the ligands A-B are identical or different; preferably, m is selected from 1;

X is selected from the group consisting of: O, S, Se, NR₂, CR₂R₂, and SiR₂R₂;

X₁ to X₄ and X₇ to X₁₂ are, at each occurrence identically or differently, selected from CRₓ or N;

Y₁ to Y₄ are, at each occurrence identically or differently, selected from CR_{y} or N;

Y is selected from SiR₃R₃, GeR₃R₃, NR₃, PR₃, O, S or Se; when two R₃ are present at the same time, the two R₃ may be identical or different;

L is, at each occurrence identically or differently, selected from B, N or P;

G₁ to G₃ are, at each occurrence identically or differently, selected from CR_{g} or N;

H₁ to H₄ are, at each occurrence identically or differently, selected from CRₕ or N;

R″, R_{c}, and R_{d} represent, at each occurrence identically or differently, mono-substitution, multiple substitutions or non-substitution;

R_{A1}, R_{A2}, R_{B}, R₂, R₃, Rₓ, R_{y}, R″, R_{c}, R_{d}, R_{g}, Rₕ, and Rᵥ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

adjacent substituents in Formula 6 can be optionally joined to form a ring;

adjacent substituents in Formula 7 can be optionally joined to form a ring;

adjacent substituents in Formula 8 can be optionally joined to form a ring;

adjacent substituents in Formula 9 can be optionally joined to form a ring.

In this embodiment, the expression that “adjacent substituents in Formula 6 can be optionally joined to form a ring” is intended to mean that any one or more of groups of adjacent substituents in Formula 6, such as two substituents Rₓ, two substituents R_{c}, two substituents R_{d}, adjacent substituents R_{c} and R_{d}, and adjacent substituents R₂ and Rₓ, can be joined to form a ring. Obviously, it is possible that none of these substituents are joined to form a ring.

In this embodiment, the expression that “adjacent substituents in Formula 7 can be optionally joined to form a ring” is intended to mean that any one or more of groups of adjacent substituents in Formula 7, such as two substituents Rₓ, two substituents R_{y}, two substituents R″, and adjacent substituents Rᵥ and R″, can be joined to form a ring. Obviously, it is possible that none of these substituents are joined to form a ring.

In this embodiment, the expression that “adjacent substituents in Formula 8 can be optionally joined to form a ring” is intended to mean that any one or more of groups of adjacent substituents in Formula 8, such as two substituents Rₓ, two substituents R_{g}, two substituents Rₕ, two substituents R₃, two substituents R_{A1}, two substituents R_{A2}, adjacent substituents R_{g} and R₃, adjacent substituents Rₓ and Rₕ, adjacent substituents Rₓ and R_{g}, adjacent substituents R_{B} and R_{A1}, adjacent substituents R_{B} and R_{A2}, can be joined to form a ring. Obviously, it is possible that none of these substituents are joined to form a ring.

In this embodiment, the expression that “adjacent substituents in Formula 9 can be optionally joined to form a ring” is intended to mean that any one or more of groups of adjacent substituents in Formula 9, such as two substituents Rₓ, two substituents R_{g}, two substituents Rₕ, two substituents R_{A1}, two substituents R_{A2}, adjacent substituents Rₓ and R_{g}, adjacent substituents R_{B} and R_{A1}, and adjacent substituents R_{B} and R_{A2}, can be joined to form a ring. Obviously, it is possible that none of these substituents are joined to form a ring.

According to an embodiment of the present disclosure, wherein, X is, at each occurrence identically or differently, selected from O or S.

According to an embodiment of the present disclosure, wherein, Y is, at each occurrence identically or differently, selected from O or S.

According to an embodiment of the present disclosure, wherein, X is O.

According to an embodiment of the present disclosure, wherein, Y is O.

According to an embodiment of the present disclosure, wherein, Rₐ, R_{b}, R_{c}, R_{d}, Rₑ, and R_{f} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a cyano group, and combinations thereof.

According to an embodiment of the present disclosure, wherein, Rₐ and/or R_{b} is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, a cyano group, and combinations thereof.

According to an embodiment of the present disclosure, wherein, R_{c} and/or R_{d} is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, a cyano group, and combinations thereof.

According to an embodiment of the present disclosure, wherein, Rₑ and/or R_{f} is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, a cyano group, and combinations thereof.

According to an embodiment of the present disclosure, wherein, at least one of X₉ to X₁₂ is selected from CRₓ, and the Rₓ is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

According to an embodiment of the present disclosure, wherein, at least one of X₉ to X₁₂ is selected from CRₓ, and the Rₓ is, at each occurrence identically or differently, substituted or unsubstituted aryl having 6 to 30 carbon atoms, substituted or unsubstituted heteroaryl having 3 to 30 carbon atoms, a cyano group, and combinations thereof.

According to an embodiment of the present disclosure, wherein, at least one of X₉ to X₁₂ is selected from CRₓ, and the Rₓ is a cyano group.

According to an embodiment of the present disclosure, wherein, X₁₀ is CRₓ, and the Rₓ is a cyano group.

According to an embodiment of the present disclosure, wherein, at least two of X₉ to X₁₂ are selected from CRₓ, and the Rₓ is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

According to an embodiment of the present disclosure, wherein, at least two of X₉ to X₁₂ are selected from CRₓ, and the Rₓ is, at each occurrence identically or differently, selected from the group consisting of: substituted or unsubstituted aryl having 6 to 30 carbon atoms, substituted or unsubstituted heteroaryl having 3 to 30 carbon atoms, a cyano group, and combinations thereof.

According to an embodiment of the present disclosure, wherein, at least two of X₉ to X₁₂ are selected from CRₓ, and one of the Rₓ is a cyano group, and at least another Rₓ is substituted or unsubstituted aryl having 6 to 30 carbon atoms or substituted or unsubstituted heteroaryl having 3 to 30 carbon atoms.

According to an embodiment of the present disclosure, wherein, X₁₀ is selected from CRₓ, and the Rₓ is a cyano group; X₉ is selected from CRₓ, and the Rₓ is substituted or unsubstituted aryl having 6 to 30 carbon atoms, or substituted or unsubstituted heteroaryl having 3 to 30 carbon atoms.

According to an embodiment of the present disclosure, wherein, X₉ to X₁₂ are, at each occurrence identically or differently, selected from N or CRₓ, and two adjacent substituents Rₓ are not joined to each other to form a ring.

According to an embodiment of the present disclosure, wherein, X₉ to X₁₂ are, at each occurrence identically or differently, selected from N or CRₓ, and two adjacent substituents Rₓ are joined to each other to form a five-membered ring.

According to an embodiment of the present disclosure, wherein, at least one or at least two of R_{c} is(are) selected from substituted or unsubstituted alkyl having 1 to 20 carbon atoms, substituted or unsubstituted cycloalkyl having 3 to 20 ring carbon atoms or combinations thereof.

According to an embodiment of the present disclosure, wherein, at least one or at least two of R_{d} is(are) selected from substituted or unsubstituted alkyl having 1 to 20 carbon atoms, substituted or unsubstituted cycloalkyl having 3 to 20 ring carbon atoms or combinations thereof.

According to an embodiment of the present disclosure, wherein, at least one or at least two of R_{c} is(are) selected from substituted or unsubstituted alkyl having 1 to 20 carbon atoms, substituted or unsubstituted cycloalkyl having 3 to 20 ring carbon atoms or combinations thereof, and the total number of carbon atoms in all R_{c} is at least 4.

According to an embodiment of the present disclosure, wherein, at least one or at least two of R_{d} is(are) selected from substituted or unsubstituted alkyl having 1 to 20 carbon atoms, substituted or unsubstituted cycloalkyl having 3 to 20 ring carbon atoms or combinations thereof, and the total number of carbon atoms in all R_{d} is at least 4.

According to an embodiment of the present disclosure, wherein, W, L₁, L₂, and L₃ are, at each occurrence identically or differently, selected from a single bond, O or S.

According to an embodiment of the present disclosure, wherein, W, L₁, L₂, and L₃ are, at each occurrence identically or differently, selected from a single bond or O.

According to an embodiment of the present disclosure, wherein, V₁ and V₂ are both selected from CRᵥ, and two Rᵥ are joined to form an aromatic ring having 6 ring atoms or a heteroaromatic ring having 6 ring atoms.

According to an embodiment of the present disclosure, wherein, V₂ and V₃ are both selected from CRᵥ, and two Rᵥ are joined to form an aromatic ring having 6 ring atoms or a heteroaromatic ring having 6 ring atoms.

According to an embodiment of the present disclosure, wherein, Rₓ, R_{y}, R_{g}, and Rᵢ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a cyano group, and combinations thereof.

According to an embodiment of the present disclosure, wherein, X₁ to X₄ and X₇ to X₈ are, at each occurrence identically or differently, selected from CRₓ; G₁ to G₃ are, at each occurrence identically or differently, selected from CR_{g}; H₁ to H₄ are, at each occurrence identically or differently, selected from CRₕ; Rₓ, R_{g}, and Rₕ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a cyano group, and combinations thereof.

According to an embodiment of the present disclosure, wherein, X₁ to X₄ and X₇ to X₈ are, at each occurrence identically or differently, selected from CRₓ; G₁ to G₃ are, at each occurrence identically or differently, selected from CR_{g}; H₁ to H₄ are, at each occurrence identically or differently, selected from CRₕ; at least two or three of Rₓ, R_{g}, and Rₕ are, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a cyano group, and combinations thereof.

According to an embodiment of the present disclosure, wherein, in Formula 8 and Formula 9, G₂ is CR_{g}, and/or H₃ is CRₕ, and/or in Formula 9, X₈ is CRₓ, and R_{g}, Rₕ, and Rₓ are, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a cyano group, and combinations thereof.

According to an embodiment of the present disclosure, wherein, in Formula 8 and Formula 9, at least one or two of R_{A1} is(are) selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms or combinations thereof.

According to an embodiment of the present disclosure, wherein, in Formula 8 and Formula 9, at least one or two of R_{A2} is(are) selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms or combinations thereof.

According to an embodiment of the present disclosure, wherein, in Formula 8 and Formula 9, at least two of R_{A1} are selected from substituted or unsubstituted alkyl having 2 to 20 carbon atoms, substituted or unsubstituted cycloalkyl having 3 to 20 ring carbon atoms, substituted or unsubstituted heteroalkyl having 2 to 20 carbon atoms or combinations thereof.

According to an embodiment of the present disclosure, wherein, in Formula 8 and Formula 9, at least two of R_{A2} are selected from substituted or unsubstituted alkyl having 2 to 20 carbon atoms, substituted or unsubstituted cycloalkyl having 3 to 20 ring carbon atoms, substituted or unsubstituted heteroalkyl having 2 to 20 carbon atoms or combinations thereof.

According to an embodiment of the present disclosure, wherein, the metal complex is, at each occurrence identically or differently, selected from the group consisting of metal complex 1 to metal complex 98, where for the specific structures of metal complex 1 to metal complex 98, reference is made to claim 23.

According to an embodiment of the present disclosure, wherein, an electroluminescent device is further disclosed, which includes an anode, a cathode and an organic layer disposed between the anode and the cathode, where at least one layer of the organic layer includes the metal complex described above.

According to an embodiment of the present disclosure, wherein, the organic layer including the metal complex is an emissive layer.

According to an embodiment of the present disclosure, wherein, the emissive layer further includes at least one first host compound.

According to an embodiment of the present disclosure, wherein, the emissive layer includes at least two host compounds.

According to an embodiment of the present disclosure, wherein, at least one of the host compounds includes at least one chemical group selected from the group consisting of: benzene, pyridine, pyrimidine, triazine, carbazole, azacarbazole, indolocarbazole, dibenzothiophene, azadibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene, and combinations thereof.

According to an embodiment of the present disclosure, wherein, the electroluminescent device is a bottom-emitting device, and the EQE of the electroluminescent device is greater than or equal to 25% at a current of 1000 cd/m².

According to an embodiment of the present disclosure, wherein, the electroluminescent device is a bottom-emitting device, and the EQE of the electroluminescent device is greater than or equal to 26% at a current of 1000 cd/m².

According to an embodiment of the present disclosure, wherein, the electroluminescent device is a bottom-emitting device, and the EQE of the electroluminescent device is greater than or equal to 27% at a current of 1000 cd/m².

According to an embodiment of the present disclosure, wherein, the electroluminescent device is a top-emitting device, and the EQE is greater than or equal to 40% at a current of 1000 cd/m².

According to an embodiment of the present disclosure, wherein, the electroluminescent device is a top-emitting device, and the EQE of the electroluminescent device is greater than or equal to 45% at a current of 1000 cd/m².

According to an embodiment of the present disclosure, wherein, the electroluminescent device is a top-emitting device, and the EQE of the electroluminescent device is greater than or equal to 50% at a current of 1000 cd/m².

According to an embodiment of the present disclosure, a compound composition is further disclosed, which includes the metal complex described in any one of embodiments described above.

In the present disclosure, the photoluminescence spectrum test method of the compounds is as follows:

The photoluminescence (PL) spectra data of the sample compounds are measured by using a fluorescence spectrophotometer F98 produced by SHANGHAI LENGGUANG TECHNOLOGY CO., LTD. The sample compounds are prepared into solutions each with a concentration of 1×10⁻⁶ mol/L using HPLC-grade toluene solution and then excited at room temperature (298 K) using light with any wavelength within the maximum absorption peak 30 nm, and their emission spectra are measured.

In the present disclosure, the method for calculating the emission spectrum area ratio is as follows:

First, the photoluminescence (PL) spectra data of the compounds of the present disclosure and comparative compounds are measured by using a fluorescence spectrophotometer F98 produced by SHANGHAI LENGGUANG TECHNOLOGY CO., LTD. The example compounds and comparative compounds are prepared into solutions each with a concentration of 1×10⁻⁶ mol/L using HPLC-grade toluene solution and then excited at room temperature (298 K) using light with any wavelength within the maximum absorption peak 30 nm, and their emission spectra are measured.

Then, the emission spectrum data is subjected to normalization (the normalization is to divide all emission intensity data by the largest value of the emission intensity), and the emission area ratio is calculated in the following manner:

1) When the maximum emission wavelength is λ₁ and λ₁ is greater than or equal to 410 nm and less than 500 nm, the calculation range is 380 nm to 700 nm. After the spectrum is normalized, the region with emission brightness greater than 0.02 under the spectrum curve is integrated to obtain the area Area 1-1. The length between 380 nm and 700 nm is multiplied by a height between 0.02 and 1.00 to obtain the area Area 1-2 as 313.6. The emission spectrum area ratio=[Area 1-1]/[Area 1-2]=[Area 1-1]/313.6=AR1.

2) When the maximum emission wavelength is λ₂ and λ₂ is greater than or equal to 500 nm and less than 580 nm, the calculation range is 420 nm to 750 nm. After the spectrum is normalized, the region with emission brightness greater than 0.02 under the spectrum curve is integrated to obtain the area Area 2-1. The length between 420 nm and 750 nm is multiplied by a height between 0.02 and 1.00 to obtain the area Area 2-2 as 323.4. The emission spectrum area ratio=[Area 2-1]/[Area 2-2]=[Area 2-1]/323.4=AR2.

3) When the maximum emission wavelength is λ₃ and λ₃ is greater than or equal to 580 nm and less than or equal to 700 nm, the calculation range is 580 nm to 870 nm. After the spectrum is normalized, the region with emission brightness greater than 0.02 under the spectrum curve is integrated to obtain Area 3-1. The length between 520 nm and 870 nm is multiplied by a height between 0.02 and 1.00 to obtain the area Area 3-2 as 343. The emission spectrum area ratio=[Area 3-1]/[Area 3-2]=[Area 3-1]/343=AR3.

For the calculation of the emission spectrum area ratio, reference may be made to FIG. 3. FIG. 3 is a normalized photoluminescence spectrogram. In FIG. 3, the maximum emission wavelength is within the wavelength range of λ₂, and when the emission area ratio is calculated, the calculation is carried out according to the method described in 2), where the area of the dark part under the curve is Area 2-1, the square area covered by black short lines is Area 2-2, and in this regard, AR2 is [Area 2-1]/[Area 2-2].

Taking the metal complex 21 of the present disclosure as an example, the maximum emission wavelength of the metal complex 21 was measured to be 538 nm. After the spectrum was normalized, the region with emission brightness greater than 0.02 under the spectrum curve was integrated to obtain the area Area 2-1 as 41.88. The length between 420 nm and 750 nm was multiplied by a height between 0.02 and 1.00 to obtain the area Area 2-2 as 323.4. The emission spectrum area ratio AR2=[Area 2-1]/[Area 2-2]=41.88/323.4=0.129.

The calculation data of the maximum emission wavelength and emission spectrum area ratio of part of metal complexes of the present disclosure and comparative compounds are shown in Table 1:

TABLE 1
Maximum emission wavelength and emission spectrum area ratio

| | λₘₐₓ | | | λₘₐₓ | |
|---|---|---|---|---|---|
| Compound No. | (nm) | AR2 | Compound No. | (nm) | AR3 |
| Metal complex 1 | 528 | 0.138 | Metal complex 41 | 619 | 0.110 |
| Metal complex 12 | 529 | 0.135 | Metal complex 90 | 620 | 0.088 |
| Metal complex 21 | 538 | 0.129 | RD1 | 622 | 0.160 |
| GD1 | 526 | 0.173 | RD2 | 630 | 0.177 |

| | | |
|---|---|---|
| GD2 | 526 | 0.166 |
| GD3 | 527 | 0.167 |

Combinations with Other Materials

The materials described in the present disclosure for a particular layer in an organic light emitting device can be used in combination with various other materials present in the device. The combinations of these materials are described in more detail in U.S. Pat. App. No. 2016/0359122A1 at paragraphs 0132-0161, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

The materials described herein as useful for a particular layer in an organic light emitting device may be used in combination with a variety of other materials present in the device. For example, light emitting dopants disclosed herein may be used in combination with a wide variety of hosts, transport layers, blocking layers, injection layers, electrodes and other layers that may be present. The combination of these materials is described in detail in paragraphs 0080-0101 of U.S. Pat. App. No. 2015/0349273A1, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

In the embodiments of material synthesis, all reactions were performed under nitrogen protection unless otherwise stated. All reaction solvents were anhydrous and used as received from commercial sources. Synthetic products were structurally confirmed and tested for properties using one or more conventional equipment in the art (including, but not limited to, nuclear magnetic resonance instrument produced by BRUKER, liquid chromatograph produced by SHIMADZU, liquid chromatograph-mass spectrometry produced by SHIMADZU, gas chromatograph-mass spectrometry produced by SHIMADZU, differential Scanning calorimeters produced by SHIMADZU, fluorescence spectrophotometer produced by SHANGHAI LENGGUANG TECH., electrochemical workstation produced by WUHAN CORRTEST, and sublimation apparatus produced by ANHUI BEQ, etc.) by methods well known to the persons skilled in the art. In the embodiments of the device, the characteristics of the device were also tested using conventional equipment in the art (including, but not limited to, evaporator produced by ANGSTROM ENGINEERING, optical testing system produced by SUZHOU FATAR, life testing system produced by SUZHOU FATAR, and ellipsometer produced by BEIJING ELLITOP, etc.) by methods well known to the persons skilled in the art. As the persons skilled in the art are aware of the above-mentioned equipment use, test methods and other related contents, the inherent data of the sample can be obtained with certainty and without influence, so the above related contents are not further described in this present disclosure.

### Material Synthesis Example

The method for preparing a compound of the present disclosure is not limited herein. Typically, the following compounds are taken as examples without limitations, and synthesis routes and preparation methods thereof are described below.

### Synthesis Example 1: Synthesis of Metal Complex 21

### Step 1

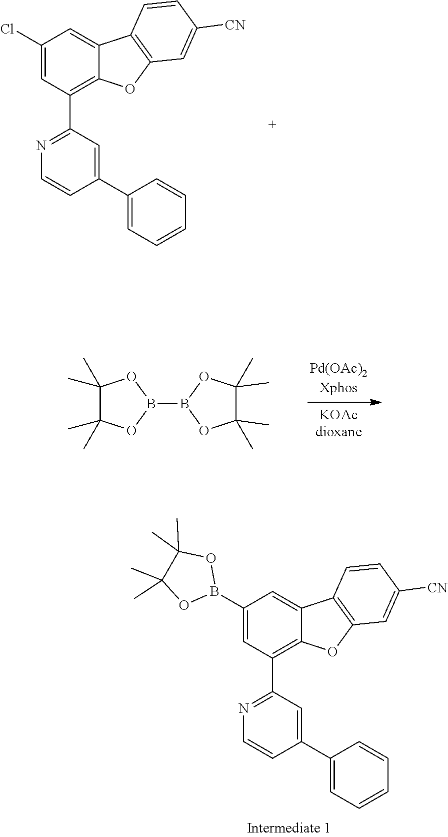

8-chloro-6-(4-phenylpyridine)-2-dibenzofuran-3-benzonitrile (1.9 g, 5.0 mmol), bis(pinacolato)diboron (1.52 g, 6.0 mmol), Xphos (0.19 g, 0.4 mmol), palladium acetate (0.05 g, 0.4 mmol), potassium acetate (0.73 g, 7.5 mmol) and dioxane (60 mL) were sequentially added to a 250 mL dry round-bottom flask, heated to reflux and stirred overnight under the protection of N₂. After the reaction was completed, the reaction solution was filtered with Celite and anhydrous magnesium sulfate and washed with ethyl acetate twice. The organic phase was collected and concentrated under reduced pressure to obtain Intermediate 1 (crude product), which was directly used for the next step.

### Step 2

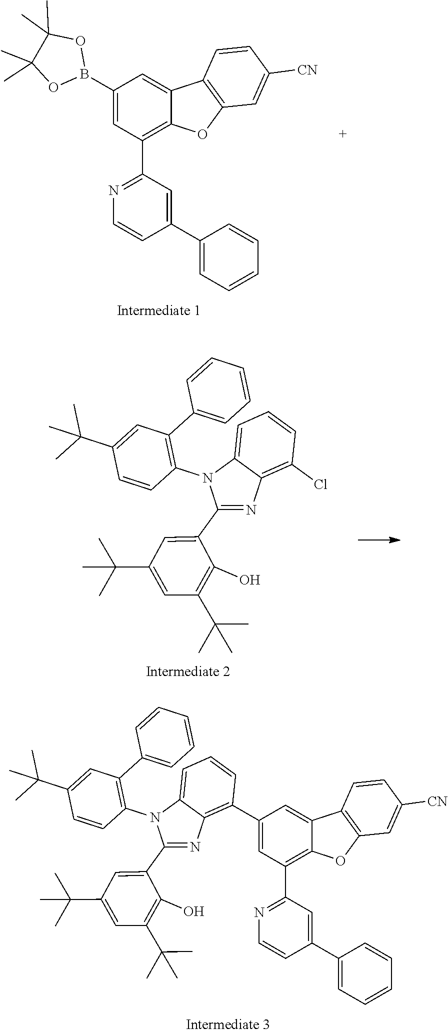 [SMILES: CC1(C)OB(c2cc(-c3cc(-c4ccccc4)ccn3)c3oc4cc(C#N)ccc4c3c2)OC1(C)C ; CC(C)(C)c1ccc(-n2c(-c3cc(C(C)(C)C)cc(C(C)(C)C)c3O)nc3c(Cl)cccc32)c(-c2ccccc2)c1 ; CC(C)(C)c1ccc(-n2c(-c3cc(C(C)(C)C)cc(C(C)(C)C)c3O)nc3c(-c4cc(-c5cc(-c6ccccc6)ccn5)c5oc6cc(C#N)ccc6c5c4)cccc32)c(-c2ccccc2)c1]

Intermediate 1 (crude product), Intermediate 2 (3.1 g, 5.5 mmol), Xphos (0.19 g, 0.4 mmol), palladium acetate (0.05 g, 0.4 mmol), potassium acetate (1.1 g, 7.5 mmol), dioxane (60 mL) and water (20 mL) were sequentially added into a dry 250 mL round-bottom flask and heated to reflux for 12 hours under the protection of N₂. After the reaction was finished, the reaction solution was extracted with dichloromethane, washed three times with saturated salt water, dried with anhydrous magnesium sulfate, and concentrated under reduced pressure. The crude product was purified by column chromatography to obtain Intermediate 3 (with a yield of 89.2%) as a white solid.

### Step 3

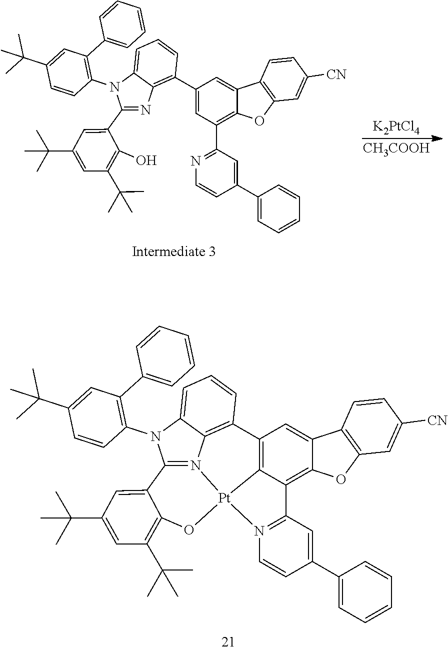

Intermediate 3 (1.53 g, 1.75 mmol), potassium chloroplatinate (0.66 g, 1.59 mmol) and acetic acid (40 mL) were sequentially added to a dry 250 mL round-bottom flask and heated to reflux for 60 hours under the protection of N₂. After the reaction was cooled, the reaction solution was added with water and filtered. The resulting precipitate was washed twice with methanol and n-hexane separately. The filter cake was dissolved with dichloromethane, the organic phase was collected, concentrated under reduced pressure and purified by column chromatography to obtain metal complex 21 as a yellow solid (0.49 g with a yield of 30.0%). The product was confirmed as the target product by NMR and LCMS with a molecular weight of 1067.4.

### Synthesis Example 2: Synthesis of Metal Complex 1

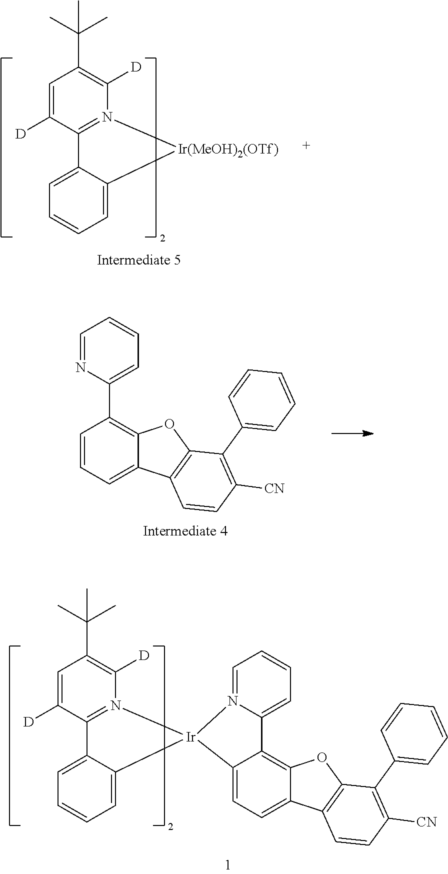

Intermediate 4 (1.6 g, 4.6 mmol), Intermediate 5 (3.18 g, 3.8 mmol), 2-ethoxyethanol (30 mL) and DMF (30 mL) were sequentially added to a dry 250 mL round-bottom flask and heated to react for 144 hours at 90° C. under the protection of N₂. After the reaction was cooled, the reaction solution was filtered with Celite. The resulting precipitate was washed twice with methanol and n-hexane separately. Yellow solids above the Celite were dissolved with dichloromethane. The organic phases were collected, concentrated under reduced pressure, and purified by column chromatography to obtain metal complex 1 as a yellow solid (0.82 g with a yield of 22.3%). The product was confirmed as the target product with a molecular weight of 962.3.

### Synthesis Example 3: Synthesis of Metal Complex 12

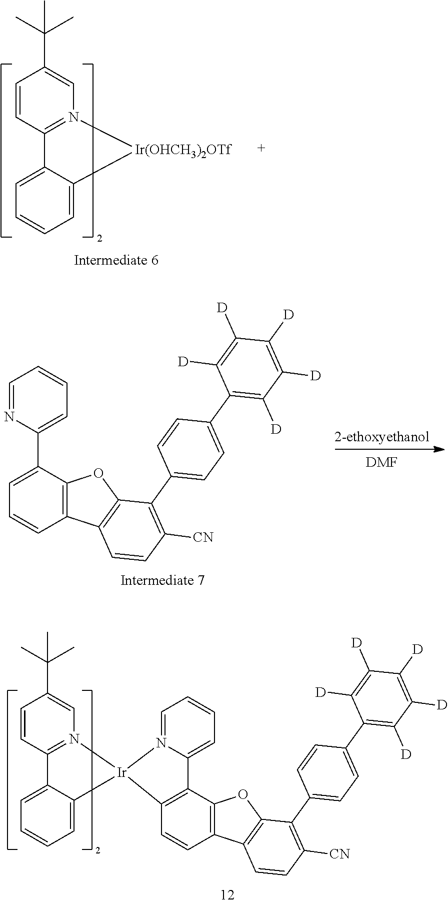

Intermediate 6 (1.4 g, 1.7 mmol), Intermediate 7 (1.0 g, 2.4 mmol), 50 mL of 2-ethoxyethanol and 50 mL of N,N-dimethylformamide were sequentially added to a dry 250 mL round-bottom flask, purged with nitrogen three times, and heated at 100° C. for 72 hours under nitrogen protection. After the reaction was cooled, the reaction solution was filtered with Celite. The resulting precipitate was washed twice with methanol and n-hexane separately. Yellow solids above the Celite were dissolved with dichloromethane. The organic phases were collected, concentrated under reduced pressure, and purified by column chromatography to give metal complex 12 as a yellow solid (0.5 g with a yield of 28.4%). The product was confirmed as the target product with a molecular weight of 1039.4.

### Synthesis Example 4: Synthesis of Metal Complex 41

### Step 1: Synthesis of Intermediate 9

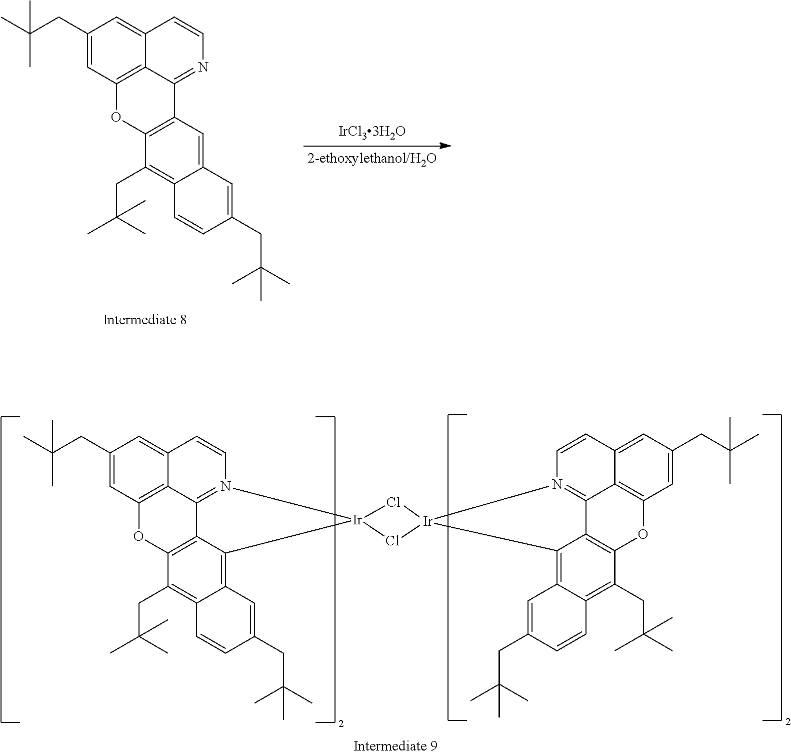

A mixture of Intermediate 8 (1.4 g, 2.92 mmol), iridium trichloride trihydrate (0.34 g, 0.97 mmol), 2-ethoxyethanol (12 mL) and water (4 mL) was refluxed in a nitrogen atmosphere for 24 hours. After the reaction was cooled to room temperature, the reaction solution was filtered to obtain iridium dimer Intermediate 9 as a red solid, which may be directly used in the next step without further purification.

### Step 2: Synthesis of Metal Complex 41

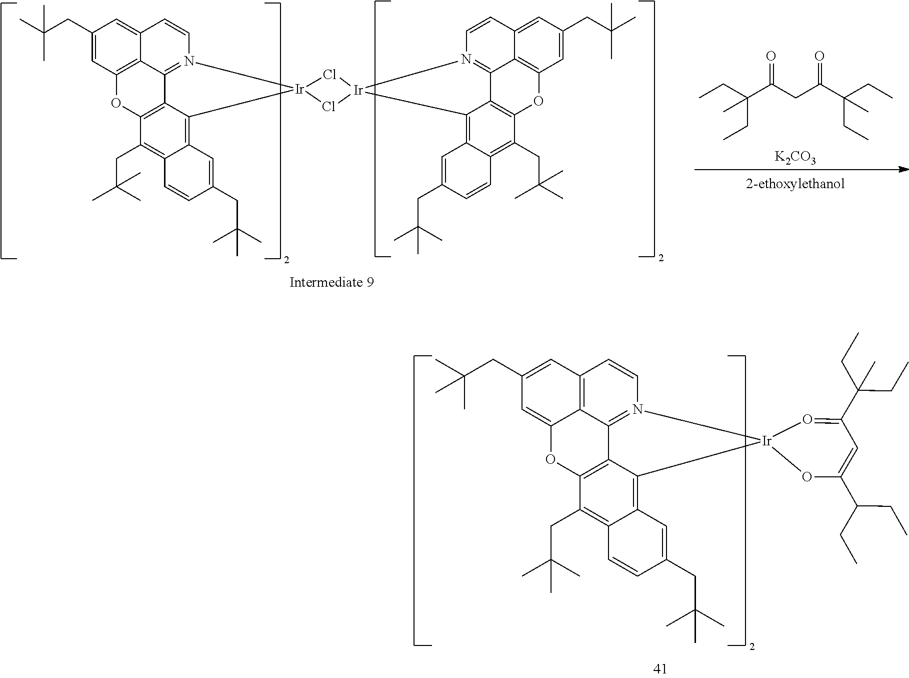

The iridium dimer Intermediate 9 obtained in the previous step, 3,7-diethyl-3-2-methylnonane-4,6-dione (0.34 g, 1.5 mmol) and potassium carbonate (0.67 g, 4.85 mmol) were dissolved in 16 mL of ethoxyethanol and reacted at 50° C. for 24 hours under nitrogen protection. Then, the reaction solution was poured into a funnel filled with Celite, filtered, and washed with ethanol. Dichloromethane was added to the resulting solid, and the filtrate was collected. Then ethanol was added, and the resulting solution was concentrated but not concentrated to dryness. The solution was filtered to obtain 0.67 g of metal complex 41 with a yield of 50%. The compound was confirmed as the target product with a molecular weight of 1374.8.

### Synthesis Example 5: Synthesis of Metal Complex 90

### Step 1: Synthesis of Intermediate 11

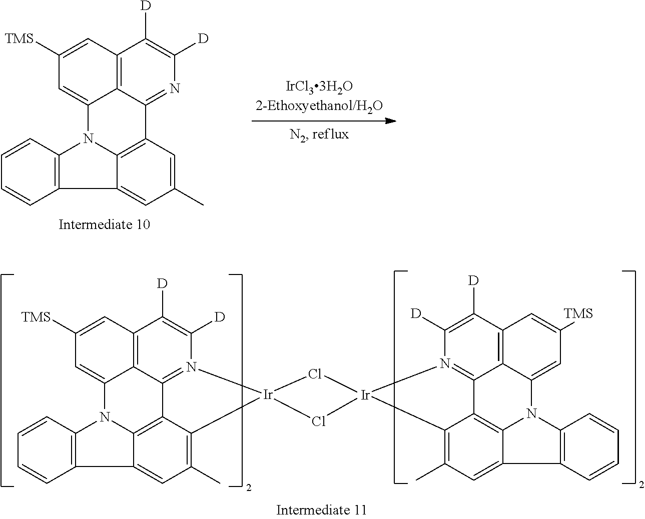

Intermediate 10 (1.8 g, 4.75 mmol) and IrCl₃ 3H₂O (465 mg, 1.32 mmol) were mixed in ethoxyethanol (27 mL) and water (9 mL), purged with nitrogen, and refluxed at 130° C. for 24 hours. After the reaction was cooled to room temperature, the reaction solution was concentrated to remove the solvent to obtain iridium dimer Intermediate 11 which may be directly used in the next step without further purification.

### Step 2: Synthesis of Metal Complex 90

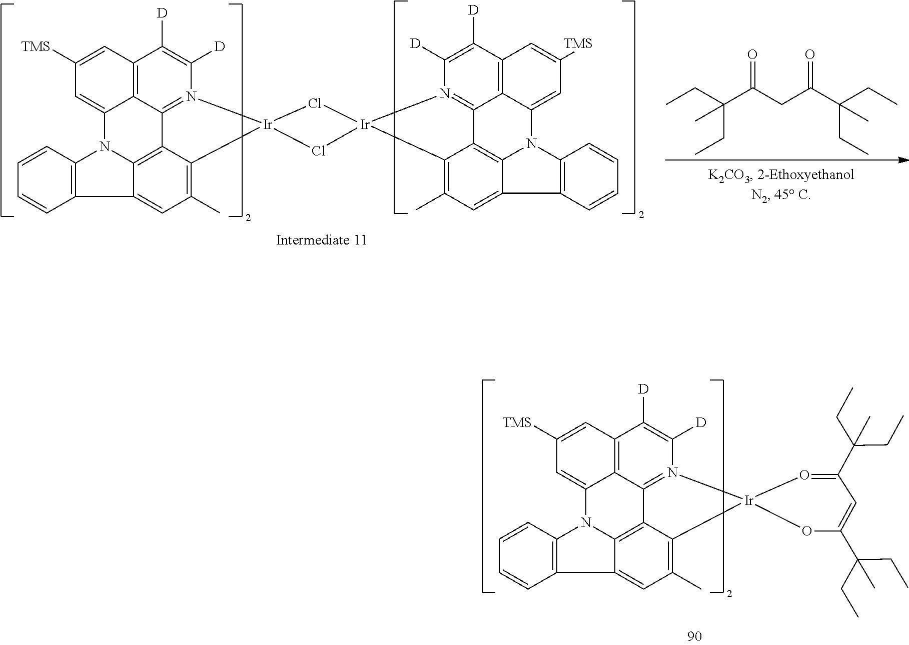

Iridium dimer Intermediate 11 prepared in step 1, 3,7-diethyl-3,7-dimethyl-4,6-nonanedione (476 mg, 1.98 mmol), K₂CO₃ (912 mg, 6.6 mmol) and ethoxyethanol (36 mL) were mixed in a 100 mL single-necked flask, purged with nitrogen, and reacted overnight at 45° C. After TLC detected that the reaction was completed, the reaction solution was cooled to room temperature. The reaction solution was filtered with Celite. The filter cake was washed with an appropriate amount of EtOH, and the crude product was washed with DCM and placed into a 250 mL flask. EtOH (about 10 mL) was added to the flask, and DCM was removed through rotary evaporation at room temperature. Then solids were precipitated, filtered and washed with an appropriate amount of EtOH to obtain the crude product. The crude product was purified by column chromatography to obtain the product metal complex 90 (300 mg). The product was confirmed as the target product with a molecular weight of 1190.5.

The persons skilled in the art will appreciate that the above preparation methods are merely examples. The persons skilled in the art can obtain other compound structures of the present disclosure through the modifications of the preparation methods.

### Bottom-Emitting Device Example

### Device Example 1

First, a glass substrate having an indium tin oxide (ITO) anode with a thickness of 80 nm was cleaned and then treated with oxygen plasma and UV ozone. After the treatment, the substrate was dried in a glovebox to remove moisture. Next, the substrate was mounted on a substrate holder and placed in a vacuum chamber. Organic layers specified below were sequentially deposited through vacuum thermal evaporation on the ITO anode at a rate of 0.01 Å/s to 10 Å/s at a vacuum degree of about 10⁻⁸ torr. Compound H1 was deposited as a hole injection layer (HIL). Compound HT was deposited as a hole transport layer (HTL). Compound H1 was used as an electron blocking layer (EBL). The metal complex 21 of the present disclosure, Compound H1 and Compound H2 were co-deposited as an emissive layer (EML). On the EML, Compound HB was used as a hole blocking layer (HBL). On the HBL, Compound ET and 8-hydroxyquinolinolato-lithium (Liq) were co-deposited as an electron transport layer (ETL). Finally, 8-hydroxyquinolinolato-lithium (Liq) with a thickness of 1 nm was deposited as an electron injection layer, and Al with a thickness of 120 nm was deposited as a cathode. The device was then transferred back to the glovebox and encapsulated with a glass lid to complete the device.

### Device Comparative Example 1

The implementation mode in Device Comparative Example 1 was the same as that in Device Example 1, except that the metal complex 21 of the present disclosure was replaced with metal complex GD1 in the emissive layer.

Detailed structures and thicknesses of layers of the devices are shown in the following table. The layers using more than one material are obtained by doping different compounds at a weight ratio as recorded in the following stable.

TABLE 2
Device structures in Example 1 and Comparative Example 1

| Device ID | HIL | HTL | EBL | EML | HBL | ETL |
|---|---|---|---|---|---|---|
| Example 1 | Compound | Compound | Compound | Compound | Compound | Compound |
| | HI | HT | H1 | H1:Compound H2:Metal | HB | ET:Liq |
| | (100 Å) | (350 Å) | (50 Å) | complex 21 | (50 Å) | (40:60) (350 Å) |
| | | | | (31:63:6) (400 Å) | | |
| Comparative | Compound | Compound | Compound | Compound | Compound | Compound |
| Example 1 | HI | HT | H1 | H1:Compound H2:Metal | HB | ET:Liq |
| | (100 Å) | (350 Å) | (50 Å) | complex GD1 | (50 Å) | (40:60) (350 Å) |
| | | | | (31:63:6) (400 Å) | | |

The structures of the materials used in the devices are shown as follows:

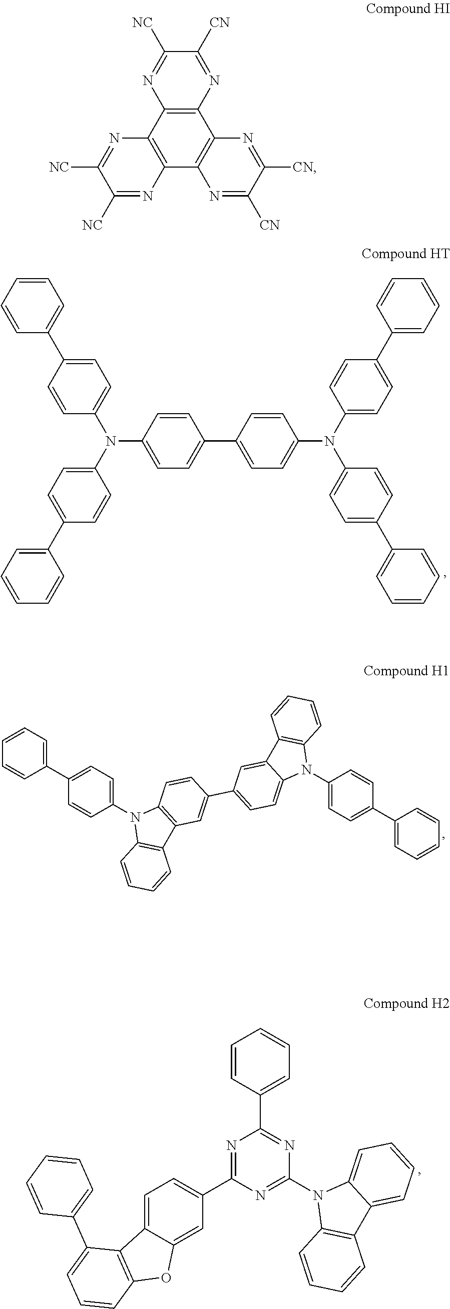 [SMILES: N#Cc1nc2c3nc(C#N)c(C#N)nc3c3nc(C#N)c(C#N)nc3c2nc1C#N ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-c2nc(-c3ccc4c(c3)oc3cccc(-c5ccccc5)c34)nc(-n3c4ccccc4c4ccccc43)n2)cc1]

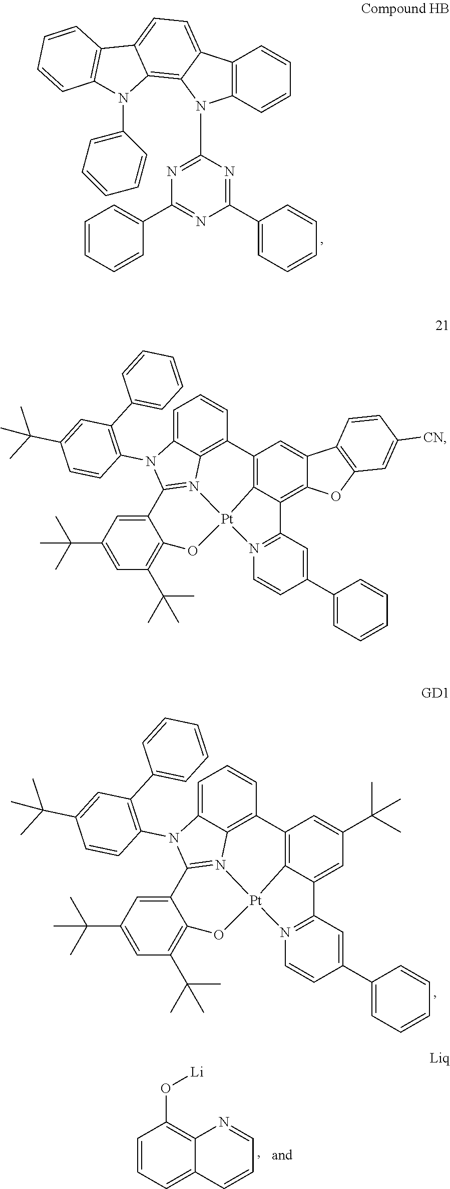

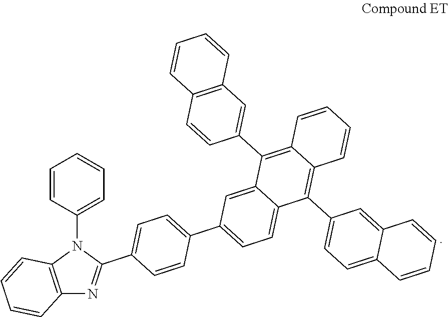 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1]

Table 3 shows the emission spectrum area ratio of the metal complex in the emissive layer and the CIE, voltage (V), current efficiency (CE), power efficiency (PE) and external quantum efficiency (EQE) of the devices in Example 1 and Comparative Example 1 at 1000 cd/m².

TABLE 3
Data of Example 1 and Comparative Example 1

| | | | Voltage | CE | PE | EQE |
|---|---|---|---|---|---|---|
| Device ID | AR 2 | CIE (x, y) | (V) | (cd/A) | (lm/W) | (%) |
| Example 1 | 0.129 | (0.404, 0.585) | 2.81 | 109 | 122 | 28.37 |
| Comparative | 0.173 | (0.342 0.625) | 3.10 | 102 | 103 | 26.83 |
| Example 1 | | | | | | |

### Discussion

As can be seen from Table 3, Example 1 containing the metal complex 21 of the present disclosure having an emission spectrum area ratio of 0.129, compared to the Comparative Example 1 containing the metal complex GD1 having a similar skeleton with metal complex 21 but an emission spectrum area ratio of 0.173, had a lower driving voltage and a higher CE, PE and EQE, among which the PE was increased by 18.4% and the EQE was increased by 5.7%, showing significant advantages in device performance. Therefore, the metal complex of the present disclosure satisfying the emission spectrum area ratio can provide better device performance in the device, especially the improvement of device efficiency.

### Device Example 2

The implementation mode in Device Example 2 was the same as that in Device Example 1, except that the metal complex 21 of the present disclosure was replaced with the metal complex 1 of the present disclosure in the emissive layer, where the ratio of Compound H1, Compound H2 and the metal complex 1 was 63:31:6.

### Device Example 3

The implementation mode in Device Example 3 was the same as that in Device Example 2, except that the metal complex 1 of the present disclosure was replaced with the metal complex 12 of the present disclosure in the emissive layer.

### Device Comparative Example 2

The implementation mode in Device Comparative Example 2 was the same as that in Device Example 2, except that the metal complex 1 of the present disclosure was replaced with the metal complex GD2 in the emissive layer.

### Device Comparative Example 3

The implementation mode in Device Comparative Example 3 was the same as that in Device Example 2, except that the metal complex 1 of the present disclosure was replaced with the metal complex GD3 in the emissive layer.

Detailed structures and thicknesses of layers of the devices are shown in the following table. The layers using more than one material are obtained by doping different compounds at a weight ratio as recorded in the following stable.

TABLE 4
Part structure of devices of Example 2-3 and Comparative Example 2-3

| Device ID | HIL | HTL | EBL | EML | HBL | ETL |
|---|---|---|---|---|---|---|
| Example 2 | Compound | Compound | Compound | Compound | Compound | Compound |
| | HI | HT | H1 | H1:Compound H2:Metal | HB | ET:Liq |
| | (100 Å) | (350 Å) | (50 Å) | complex 1 | (50 Å) | (40:60) (350 Å) |
| | | | | (63:31:6) (400 Å) | | |
| Example 3 | Compound | Compound | Compound | Compound | Compound | Compound |
| | HI | HT | H1 | H1:Compound H2:Metal | HB | ET:Liq |
| | (100 Å) | (350 Å) | (50 Å) | complex 12 | (50 Å)) | (40:60) (350 Å) |
| | | | | (63:31:6) (400 Å) | | |
| Comparative | Compound | Compound | Compound | Compound | Compound | Compound |
| Example 2 | HI | HT | H1 | H1:Compound H2:Metal | HB | ET:Liq |
| | (100 Å) | (350 Å) | (50 Å) | complex GD2 | (50 Å) | (40:60) (350 Å) |
| | | | | (63:31:6) (400 Å) | | |
| Comparative | Compound | Compound | Compound | Compound | Compound | Compound |
| Example 3 | HI | HT | H1 | H1:Compound H2:Metal | HB | ET:Liq |
| | (100 Å) | (350 Å) | (50 Å) | complex GD3 | (50 Å) | (40:60) (350 Å) |
| | | | | (63:31:6) (400 Å) | | |

Structures of the new materials used in the device are as follows:

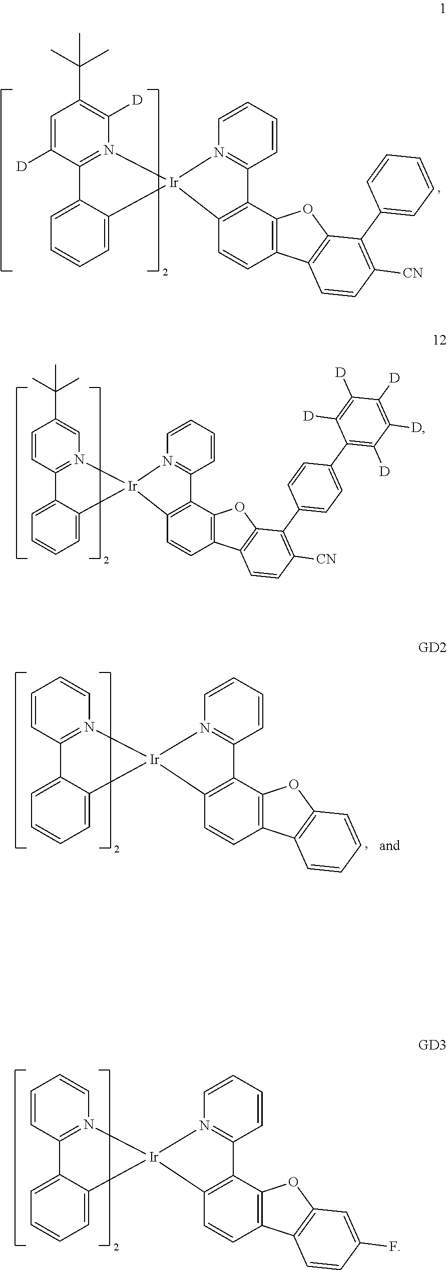

Table 5 shows the emission spectrum area ratio of the metal complex in the emissive layer and the CIE, voltage (V), current efficiency (CE), power efficiency (PE) and external quantum efficiency (EQE) of the devices in Examples 2 and 3 and Comparative Examples 2 and 3 at 1000 cd/m².

TABLE 5
Data of Examples 2 and 3 and Comparative Examples 2 and 3

| | | | Voltage | CE | PE | EQE |
|---|---|---|---|---|---|---|
| Device ID | AR2 | CIE (x, y) | (V) | (cd/A) | (lm/W) | (%) |
| Example 2 | 0.138 | (0.346, 0.631) | 2.70 | 103 | 120 | 26.14 |
| Example 3 | 0.135 | (0.344, 0.634) | 2.65 | 112 | 133 | 28.33 |
| Comparative | 0.166 | (0.334, 0.634) | 2.95 | 91 | 97 | 23.55 |
| Example 2 | | | | | | |
| Comparative | 0.167 | (0.340, 0.630) | 2.94 | 94 | 101 | 24.40 |
| Example 3 | | | | | | |

### Discussion

As can be seen from Table 5, the emission spectral area ratios of the luminescent materials used in Examples 2 and 3 were 0.138 and 0.135, respectively, both less than 0.145; and the emission spectral area ratios of the luminescent materials used in Comparative Examples 2 and 3, which had the same skeleton as the luminescent materials used in Examples 2 and 3, were 0.166 and 0.167, respectively. Compared with Comparative Examples 2 and 3, Example 2 showed significant advantages in all aspects of device performance, especially the improvement of device efficiency, where the CE was increased by 13% and 10%, respectively, the PE was increased by 24% and 19%, respectively, and the EQE was increased by 11% and 7%, respectively. Likewise, compared with Comparative Examples 2 and 3, Example 3 had significant advantages in device efficiency, where the CE was increased by 23% and 19%, the PE was increased by 37% and 32%, respectively, and the EQE was increased by 20% and 16%, respectively. Therefore, the metal complex of the present disclosure satisfying the emission spectrum area ratio can provide better device performance in the device, especially the improvement of device efficiency.

### Device Example 4

First, a glass substrate having an indium tin oxide (ITO) anode with a thickness of 120 nm was cleaned and then treated with oxygen plasma and UV ozone. After the treatment, the substrate was dried in a glovebox to remove moisture. Next, the substrate was mounted on a substrate holder and placed in a vacuum chamber. Organic layers specified below were sequentially deposited through vacuum thermal evaporation on the ITO anode at a rate of 0.01 Å/s to 10 Å/s at a vacuum degree of about 10⁻⁸ torr. Compound H1 was used as a hole injection layer (HIL) with a thickness of 100 Å. Compound HT was used as a hole transporting layer (HTL) with a thickness of 400 Å. Compound EB was used as an electron blocking layer (EBL) with a thickness of 50 Å. The metal complex 41 of the present disclosure and Compound RH were co-doped as an emissive layer (EML, at a weight ratio of 2:98) with a thickness of 400 Å. Compound HB was used as a hole blocking layer (HBL) with a thickness of 50 Å. On the HBL, Compound ET and 8-hydroxyquinolinolato-lithium (Liq) were co-deposited as an electron transport layer (ETL) with a thickness of 350 Å. Finally, Liq with a thickness of 10 Å was deposited as an electron injection layer, and A1 with a thickness of 1200 Å was deposited as a cathode. The device was then transferred back to the glovebox and encapsulated with a glass lid to complete the device.

### Device Example 5

The implementation mode in Device Example 5 was the same as that in Device Example 4, except that the metal complex 41 of the present disclosure was replaced with the metal complex 90 in the emissive layer (EML), where the ratio of Compound RH to the metal complex 90 was 97:3.

### Device Comparative Example 4

The preparation method in Device Comparative Example 4 was the same as that in Device Example 4, except that the metal complex 41 of the present disclosure was replaced with the metal complex RD1 in the emissive layer (EML).

### Device Comparative Example 5

The preparation method in Device Comparative Example 5 was the same as that in Device Example 5, except that the metal complex 90 of the present disclosure was replaced with the metal complex RD2 in the emissive layer (EML).

The structures and thicknesses of some layers of the devices are shown in the following table. The layer using more than one material was obtained by doping different compounds at their weight proportions as recorded.

TABLE 6
Part structure of devices of Examples 4 and 5 and Comparative Examples 4 and 5

| Device No. | HIL | HTL | EBL | EML | HBL | ETL |
|---|---|---|---|---|---|---|
| Example 4 | Compound | Compound | Compound | Compound RH:Metal | Compound | Compound |
| | HI | HT | EB | complex 41 | HB | ET:Liq |
| | (100 Å) | (400 Å) | (50 Å) | (98:2) (400 Å) | (50 Å) | (40:60) (350 Å) |
| Example 5 | Compound | Compound | Compound | Compound RH:Metal | Compound | Compound |
| | HI | HT | EB | complex 90 | HB | ET:Liq |
| | (100 Å) | (400 Å) | (50 Å) | (97:3) (400 Å) | (50 Å) | (40:60) (350 Å) |
| Comparative | Compound | Compound | Compound | Compound RH:Metal | Compound | Compound |
| Example 4 | HI | HT | EB | complex RD1 | HB | ET:Liq |
| | (100 Å) | (400 Å) | (50 Å) | (98:2) (400 Å) | (50 Å) | (40:60) (350 Å) |
| Comparative | Compound | Compound | Compound | Compound RH:Metal | Compound | Compound |
| Example 5 | HI | HT | EB | complex RD2 | HB | ET:Liq |
| | (100 Å) | (400 Å) | (50 Å) | (97:3) (400 Å) | (50 Å) | (40:60) (350 Å) |

The structures of the new materials used in the devices are shown as follows:

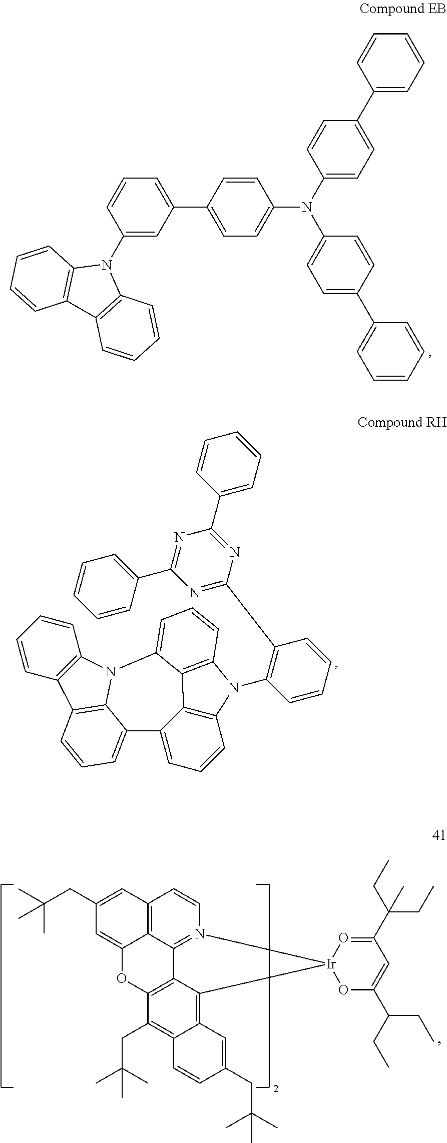

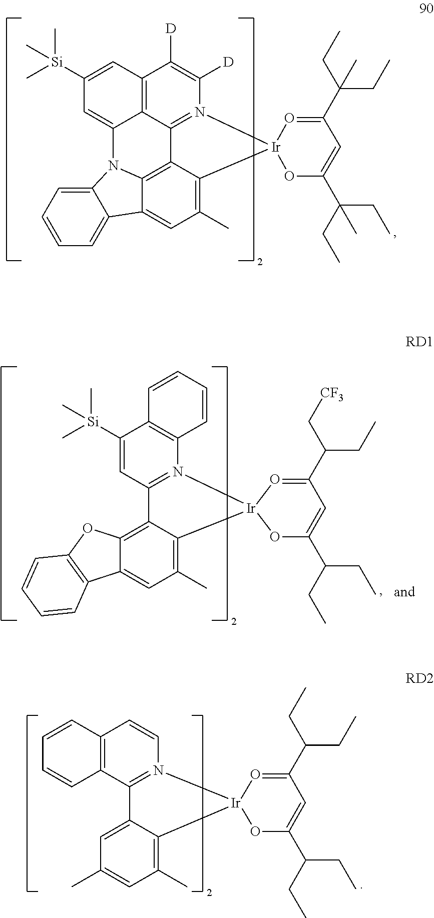

Table 7 shows the emission spectrum area ratio of the metal complex in the emissive layer and the CIE, voltage (V), current efficiency (CE), power efficiency (PE) and external quantum efficiency (EQE) of the devices in Examples 4 and 5 and Comparative Examples 4 and 5 at 1000 cd/m².

TABLE 7
Data of Examples 4 and 5 and Comparative Examples 4 and 5

| | | | Voltage | CE | PE | EQE |
|---|---|---|---|---|---|---|
| Device ID | AR3 | CIE (x, y) | (V) | (cd/A) | (lm/W) | (%) |
| Example 4 | 0.110 | (0.683, 0.316) | 3.06 | 28 | 29 | 26.80 |
| Example 5 | 0.088 | (0.692, 0.307) | 3.14 | 22 | 22 | 24.96 |
| Comparative | 0.160 | (0.682, 0.317) | 2.70 | 19 | 21 | 23.00 |
| Example 4 | | | | | | |
| Comparative | 0.177 | (0.696, 0.303) | 3.3 | 15 | 14 | 23.01 |
| Example 5 | | | | | | |

### Discussion

As can be seen from Table 7, the emission spectral area ratios of the luminescent materials used in Examples 4 and 5 were 0.110 and 0.088, respectively, both less than 0.145, and the emission spectral area ratios of the luminescent materials used in Comparative Examples 4 and 5 were 0.160 and 0.177, respectively. Compared with Comparative Examples 4 and 5, Example 4 had significant improvement in device efficiency, and especially the EQE was increased by 16.5%. In addition, the PE was also increased significantly and increased by 38% and 107%, respectively, and the CE was increased by 47.4% and 86.7%, respectively. Likewise, compared with Comparative Examples 4 and 5, Example 5 had significant advantages in device efficiency, and the efficiency was increased by 8.5%. In addition, the PE was increased by 4.7% and 57%, respectively, and the CE was increased by 15.8% and 46.7%, respectively. Therefore, the metal complex of the present disclosure satisfying the emission spectrum area ratio can provide better device performance in the device, especially the improvement of device efficiency.

To sum up, when the metal complex of the present disclosure is applied to a bottom-emitting device, the device efficiency is significantly improved, compared with the metal complex which does not satisfy the emission spectrum area ratio.

### Top-Emitting Device Example

### Device Example 6

First, a glass substrate with a thickness of 0.7 mm was used, on which indium tin oxide (ITO) with a thickness of 75 Å/Ag with a thickness of 1500 Å/ITO with a thickness of 150 Å were patterned as an anode, where ITO with a thickness of 150 Å deposited on Ag played a role of the hole injection role. Then, the substrate was dried in a glovebox to remove moisture, loaded on a support and transferred into a vacuum chamber. Organic layers specified below were sequentially deposited through vacuum thermal evaporation on the anode at a rate of 0.01 Å/s to 10 Å/s at a vacuum degree of about 10⁻⁶ torr. First, Compound H1 was deposited as a hole injection layer (HIL, 100 Å). Compound HT was deposited as a hole transport layer (HTL, 1400 Å) on HIL, and the HTL was also used as a microcavity adjustment layer. Next, Compound H1 was deposited on the hole transport layer as an electron blocking layer (EBL, 50 Å). Then the metal complex 1 of the present disclosure, Compound H1 and Compound H2 were co-deposited as an emissive layer (EML, 6:63:31, 400 Å). Compound HB was deposited as a hole blocking layer (HBL, 50 Å). Compound ET and Liq were co-deposited as an electron transport layer (ETL, 40:60, 350 Å). Metal Yb with a thickness of 10 Å was deposited as an electron injection layer (EIL). Metal Ag and Mg with a thickness of 140 Å were co-deposited as a cathode according to the ratio of 9:1. Compound CP with a thickness of 650 Å was deposited as a capping layer. The device was then transferred back to the glovebox and encapsulated with a glass lid in a nitrogen atmosphere to complete the device.

### Device Example 7

The implementation mode in Device Example 7 was the same as that in Device Example 6, except that the metal complex 1 of the present disclosure was replaced with the metal complex 12 of the present disclosure in the emissive layer, where the ratio of Compound H1, Compound H2 and the metal complex 12 was 58:38:4.

The structures and thicknesses of some layers of the devices are shown in the following table. The layer using more than one material was obtained by doping different compounds at their weight proportions as recorded.

TABLE 8
Part structure of devices of Examples 6 and 7

| Device ID | HIL | HTL | EBL | EML | HBL | ETL |
|---|---|---|---|---|---|---|
| Example 6 | Compound | Compound | Compound | Compound H1:Compound | Compound | Compound |
| | HI | HT | H1 | H2:Metal complex 1 | HB | ET:Liq |
| | (100 Å) | (1400 Å) | (50 Å) | (63:31:6) (400 Å) | (50 Å) | (40:60) (350 Å) |
| Example 7 | Compound | Compound | Compound | Compound H1:Compound | Compound | Compound |
| | HI | HT | H1 | H2:Metal complex 12 | HB | ET:Liq |
| | (100 Å) | (1400 Å) | (50 Å) | (58:38:4) (400 Å) | (50 Å) | (40:60) (350 Å) |

The structures of the new materials used in the devices are shown as follows:

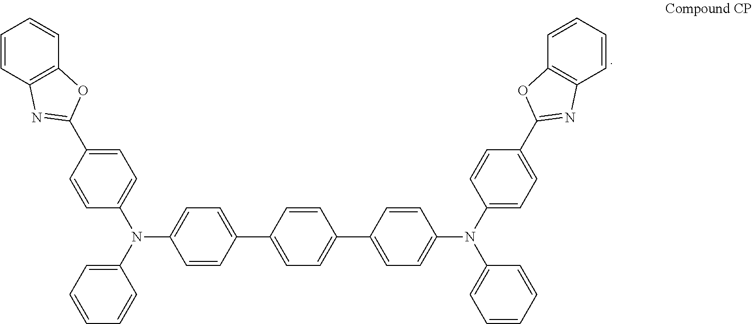 [SMILES: c1ccc(N(c2ccc(-c3ccc(-c4ccc(N(c5ccccc5)c5ccc(-c6nc7ccccc7o6)cc5)cc4)cc3)cc2)c2ccc(-c3nc4ccccc4o3)cc2)cc1]

Table 9 shows the emission spectrum area ratio of the metal complex in the emissive layer and the CIE, voltage (V), current efficiency (CE), power efficiency (PE) and external quantum efficiency (EQE) of the devices in Examples 6 and 7 at 1000 cd/m².

TABLE 9
Data of Examples 6 and 7

| | | | Voltage | CE | PE | EQE |
|---|---|---|---|---|---|---|
| Device ID | AR2 | CIE (x, y) | (V) | (cd/A) | (lm/W) | (%) |
| Example 6 | 0.138 | (0.246, 0.729) | 2.56 | 188 | 231 | 42.15 |
| Example 7 | 0.135 | (0.223, 0.745) | 2.53 | 218 | 271 | 50.42 |

### Discussion

As can be seen from Table 9, the metal complexes of the present disclosure satisfying the specific emission spectral area ratio (less than 0.145) had excellent performance in the top-emitting device. The CE, EQE and PE of the device reached very high levels within the color coordinate range of green light. It is shown that the metal complex having the characteristics of the present disclosure had significant advantages in organic electroluminescent devices.

### Device Example 8

First, a glass substrate with a thickness of 0.7 mm was used, on which indium tin oxide (ITO) with a thickness of 75 Å/Ag with a thickness of 1500 Å/ITO with a thickness of 150 Å were patterned as an anode, where ITO with a thickness of 150 Å deposited on Ag played a role of the hole injection role. Then, the substrate was dried in a glovebox to remove moisture, loaded on a support and transferred into a vacuum chamber. Organic layers specified below were sequentially deposited through vacuum thermal evaporation on the anode at a rate of 0.01 Å/s to 10 Å/s at a vacuum degree of about 10⁻⁶ torr. First, Compound HT and Compound PD were co-deposited as a hole injection layer (HIL, 98:2, 100 Å). Compound HT was deposited as a hole transport layer (HTL, 1800 Å) on HIL, and the HTL was also used as a microcavity adjustment layer. Next, Compound EB was deposited on the hole transport layer as an electron blocking layer (EBL, 50 Å). Then the metal complex 41 and Compound RH were co-deposited as an emissive layer (EML, 2:98, 400 Å). Compound HB was deposited as a hole blocking layer (HBL, 50 Å). Compound ET and Liq were co-deposited as an electron transport layer (ETL, 40:60, 350 Å). Metal Yb with a thickness of 10 Å was deposited as an electron injection layer (EIL). Metal Ag and Mg with a thickness of 140 Å were co-deposited as a cathode according to the ratio of 9:1. Compound CP with a thickness of 650 Å was deposited as a capping layer. The device was then transferred back to the glovebox and encapsulated with a glass lid and a moisture absorbent in a nitrogen atmosphere to complete the device.

### Device Comparative Example 6

The preparation method in Device Comparative Example 6 was the same as that in Device Example 8, except that the metal complex 41 of the present disclosure was replaced with the metal complex RD3 in the emissive layer (EML).

The structures and thicknesses of some layers of the devices are shown in the following table. The layer using more than one material was obtained by doping different compounds at their weight proportions as recorded.

TABLE 10
Part structure of devices of Example 8 and Comparative Example 6

| Device No. | HIL | HTL | EBL | EML | HBL | ETL |
|---|---|---|---|---|---|---|
| Example 8 | Compound | Compound | Compound | Compound RH:Metal | Compound | Compound |
| | HT:Compound PD | HT | EB | complex 41 | HB | ET:Liq |
| | (98:2) (100 Å) | (1800 Å) | (50 Å) | (98:2) (400 Å) | (50 Å) | (40:60) (350 Å) |
| Comparative | Compound | Compound | Compound | Compound RH:Metal | Compound | Compound |
| Example 6 | HT:Compound PD | HT | EB | complex RD3 | HB | ET:Liq |
| | (98:2) (100 Å) | (1800 Å) | (50 Å) | (98:2) (400 Å) | (50 Å) | (40:60) (350 Å) |

The structures of the new materials used in the devices are shown as follows:

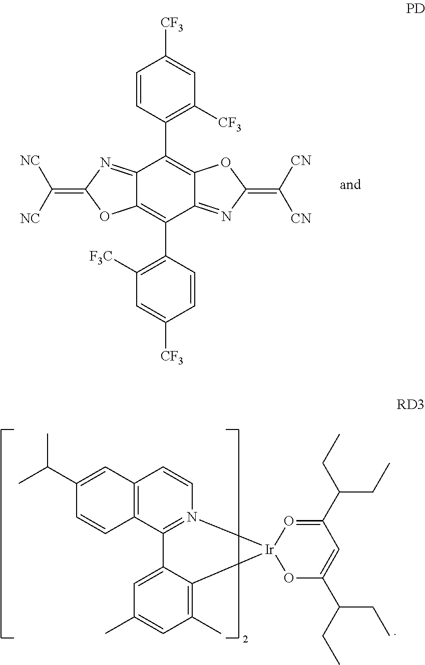

Table 11 shows the emission spectrum area ratio of the metal complex in the emissive layer and the CIE, voltage (V), current efficiency (CE), power efficiency (PE) and external quantum efficiency (EQE) of the devices in Example 8 and Comparative Example 6 at 1000 cd/m².

TABLE 11
Data of Example 8 and Comparative Example 6

| | | | Voltage | CE | PE | EQE |
|---|---|---|---|---|---|---|
| Device ID | AR3 | CIE (x, y) | (V) | (cd/A) | (lm/W) | (%) |
| Example 8 | 0.110 | (0.684, 0.315) | 3.03 | 76 | 79 | 50.80 |
| Comparative | 0.150 | (0.684, 0.316) | 3.30 | 64 | 61 | 45.50 |
| Example 6 | | | | | | |

### Discussion

As can be seen from Table 11, the metal complexes satisfying the specific emission spectral area ratio (less than 0.145) of the present disclosure had excellent performance in the top-emitting device. The top-emitting color of Example 8 and Comparative Example 6 was equivalent, and CIEx was 0.684. Compared with Comparative Example 6, the CE, EQE and PE of Example 8 were increased by 18.8%, 11.6% and 29.5%, respectively, and the voltage was reduced by 0.27 V, so that the comprehensive performance of the device reached a very high level. It is shown that the metal complex having the characteristics of the present disclosure had significant advantages in organic electroluminescent devices.

To sum up, through the above discussion of the metal complexes of the present disclosure in top-emitting and bottom-emitting devices, respectively, it can be shown that the metal complexes having the characteristics of the present disclosure have significant advantages in organic electroluminescent devices and in particular, obtain the improved device efficiency.

It should be understood that various embodiments described herein are merely examples and not intended to limit the scope of the present disclosure. Therefore, it is apparent to the persons skilled in the art that the present disclosure as claimed may include variations from specific embodiments and preferred embodiments described herein. Many of materials and structures described herein may be substituted with other materials and structures without departing from the spirit of the present disclosure. It should be understood that various theories as to why the present disclosure works are not intended to be limitative.

What is claimed is:

1. A metal complex, wherein the maximum emission wavelength of the photoluminescence spectrum of the metal complex at room temperature is greater than or equal to 410 nm and less than or equal to 700 nm;
when the maximum emission wavelength is λ₁ and λ₁ is greater than or equal to 410 nm and less than 500 nm, the emission spectrum area ratio of the metal complex is AR1, and AR1 is less than or equal to 0.145;
when the maximum emission wavelength is λ₂ and λ₂ is greater than or equal to 500 nm and less than 580 nm, the emission spectrum area ratio of the metal complex is AR2, and AR2 is less than or equal to 0.145;
when the maximum emission wavelength is λ₃ and λ₃ is greater than or equal to 580 nm and less than or equal to 700 nm, the emission spectrum area ratio of the metal complex is AR3, and AR3 is less than or equal to 0.145;
the emission intensity of the metal complex is less than or equal to 0.2 at wavelengths of 380 nm and 780 nm;
the metal complex comprises a metal M and at least one C\hat{ }N bidentate ligand Lₐ coordinated with the metal M;
the metal M is selected from metals having a relative atomic mass greater than 40;
the ligand Lₐ at least comprises ring A and B, which are directly linked;
the ring A is, at each occurrence identically or differently, selected from a substituted or unsubstituted heteroaromatic ring having 5 to 6 ring atoms;
the ring B is, at each occurrence identically or differently, selected from a substituted or unsubstituted benzene ring or a substituted or unsubstituted heteroaromatic ring having 5 to 6 ring atoms;
the ring A is linked to the metal through a metal-nitrogen bond;
the ring B is linked to the metal through a metal-carbon bond;
adjacent substituents in rings A and B can be optionally joined to form a ring.

2. The metal complex of claim 1, wherein the maximum emission wavelength of the photoluminescence spectrum of the metal complex at room temperature is greater than or equal to 420 nm and less than or equal to 480 nm; or the maximum emission wavelength is greater than or equal to 500 nm and less than or equal to 560 nm; or the maximum emission wavelength is greater than or equal to 580 nm and less than or equal to 650 nm;
preferably, the maximum emission wavelength of the photoluminescence spectrum of the metal complex at room temperature is greater than or equal to 440 nm and less than or equal to 470 nm; or the maximum emission wavelength is greater than or equal to 500 nm and less than or equal to 540 nm; or the maximum emission wavelength is greater than or equal to 600 nm and less than or equal to 640 nm.

3. The metal complex of claim 1, wherein AR2 of the metal complex is less than or equal to 0.140 and/or AR3 is less than or equal to 0.130;
preferably, AR2 of the metal complex is less than or equal to 0.138 and/or AR3 is less than or equal to 0.120;
more preferably, AR2 of the metal complex is less than or equal to 0.135 and/or AR3 is less than or equal to 0.110.

4. The metal complex of claim 1, wherein the metal complex has a structure represented by Formula I or Formula II: 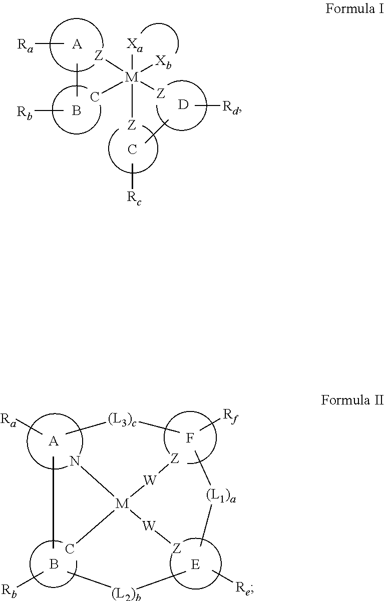
wherein
the metal M is selected from metals having a relative atomic mass greater than 40;
ligand C-D is identical to or different from ligand A-B;
ligand E-(L₁)ₐ-F is identical to or different from ligand A-B;
ligand 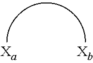
represents a monoanionic bidentate ligand and is identical to or different from ligand A-B;
the ring A is selected from a substituted or unsubstituted heteroaromatic ring having 5 to 6 ring atoms;
the ring B is selected from a substituted or unsubstituted benzene ring or a substituted or unsubstituted heteroaromatic ring having 6 ring atoms;
ring C, ring D, ring E, and ring F are, at each occurrence identically or differently, selected from an aromatic ring having 6 to 30 carbon atoms, a heteroaromatic ring having 3 to 30 carbon atoms or combinations thereof;
Z is, at each occurrence identically or differently, selected from C or N;
W is, at each occurrence identically or differently, selected from a single bond, O, S, Se, NR′, CR′R′ and SiR′R; when two R′ are present at the same time, the two R′ are identical or different;
Xₐ and X_{b} are, at each occurrence identically or differently, selected from C, N, O, S or Se;
L₁, L₂, and L₃ are, at each occurrence identically or differently, selected from the group consisting of: a single bond, BR₁, CR₁R₁, NR₁, SiR₁R₁, PR₁, GeR₁R₁, O, S, Se, substituted or unsubstituted vinylene, ethynylene, substituted or unsubstituted arylene having 5 to 30 carbon atoms, substituted or unsubstituted heteroarylene having 5 to 30 carbon atoms, and combinations thereof; when two R₁ are present at the same time, the two R₁ are identical or different;
a, b, and c are, at each occurrence identically or differently, selected from 0 or 1;
Rₐ, R_{b}, R_{c}, R_{d}, Rₑ, and R_{f} represent, at each occurrence identically or differently, mono-substitution, multiple substitutions or non-substitution;
R′, Rₐ, R_{b}, R_{c}, R_{d}, Rₑ, R_{f}, and R₁ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R′, Rₐ, R_{b}, R_{c}, R_{d}, Rₑ, R_{f}, and R₁ can be optionally joined to form a ring.

5. The metal complex of claim 1, wherein the metal M is, at each occurrence identically or differently, selected from the group consisting of Cu, Ag, Au, Ru, Rh, Pd, Os, Ir and Pt;
preferably, the metal M is, at each occurrence identically or differently, selected from Pt or Ir.

6. The metal complex of claim 1, wherein the ligand Lₐ (ligand A-B) is, at each occurrence identically or differently, selected from structures represented by Formula 1 and/or Formula 2: 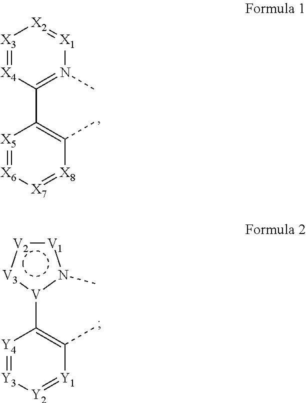
wherein
V is, at each occurrence identically or differently, selected from C or N;
V₁ to V₃ are, at each occurrence identically or differently, selected from O, S, N, CRᵥ or NRᵥ;
X₁ to X₈ are, at each occurrence identically or differently, selected from CRₓ or N;
Y₁ to Y₄ are, at each occurrence identically or differently, selected from CR_{y} or N;
Rᵥ, Rₓ, and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents in Formula 1 can be optionally joined to form a ring;
adjacent substituents in Formula 2 can be optionally joined to form a ring.

7. The metal complex of claim 1, wherein the ligand A-B is, at each occurrence identically or differently, has a structure represented by Formula 3, Formula 4 or Formula 5: 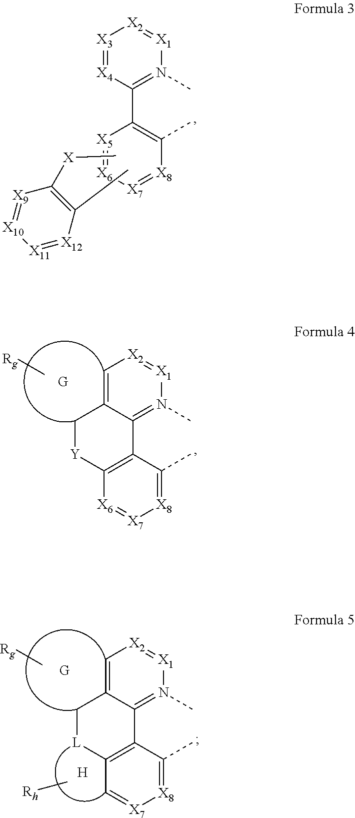
wherein
ring G is, at each occurrence identically or differently, selected from a five-membered unsaturated carbocyclic ring, an aromatic ring having 6 to 30 carbon atoms or a heteroaromatic ring having 3 to 30 carbon atoms;
ring H is, at each occurrence identically or differently, selected from a heterocyclic ring having 2 to 30 carbon atoms or a heteroaromatic ring having 2 to 30 carbon atoms;
X is selected from the group consisting of O, S, Se, NR₂, CR₂R₂, and SiR₂R₂, and when two R₂ are present at the same time, the two R₂ are identical or different;
Y is selected from the group consisting of O, S, Se, SiR₃R₃, GeR₃R₃, NR₃, and PR₃, and when two R₃ are present at the same time, the two R₃ are identical or different;
L is, at each occurrence identically or differently, selected from B, N or P;
X₁ to X₁₂ are, at each occurrence identically or differently, selected from C, CRₓ or N;
R_{g} and Rₕ represent, at each occurrence identically or differently, mono-substitution, multiple substitutions or non-substitution;
R₂, R₃, Rₓ, R_{g}, and Rₕ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents in Formula 3 can be optionally joined to form a ring;
adjacent substituents in Formula 4 can be optionally joined to form a ring;
adjacent substituents in Formula 5 can be optionally joined to form a ring.

8. The metal complex of claim 7, wherein the ligand A-B has a structure represented by Formula 4-1: 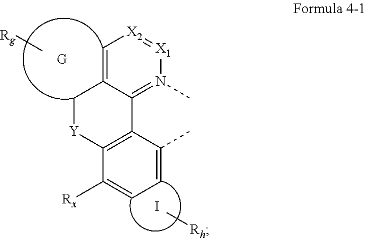
wherein ring G and ring I are, at each occurrence identically or differently, selected from a five-membered unsaturated carbocyclic ring, an aromatic ring having 6 to 30 carbon atoms or a heteroaromatic ring having 3 to 30 carbon atoms;
Y is selected from the group consisting of O, S, Se, SiR₃R₃, GeR₃R₃, NR₃, and PR₃, and when two R₃ are present at the same time, the two R₃ are identical or different;
X₁ and X₂ are, at each occurrence identically or differently, selected from CRₓ or N;
R_{g} and Rₕ represent, at each occurrence identically or differently, mono-substitution, multiple substitutions or non-substitution;
R_{g}, Rₕ, R₃, and Rₓ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a sulfanyl group, a sulfinyl group, a sulfonyl group, a phosphino group, and combinations thereof;
adjacent substituents R_{g}, Rₕ, R₃, and Rₓ in Formula 4-1 can be optionally joined to form a ring;
preferably, the ligand A-B is, at each occurrence identically or differently, selected from the group consisting of the following structures: 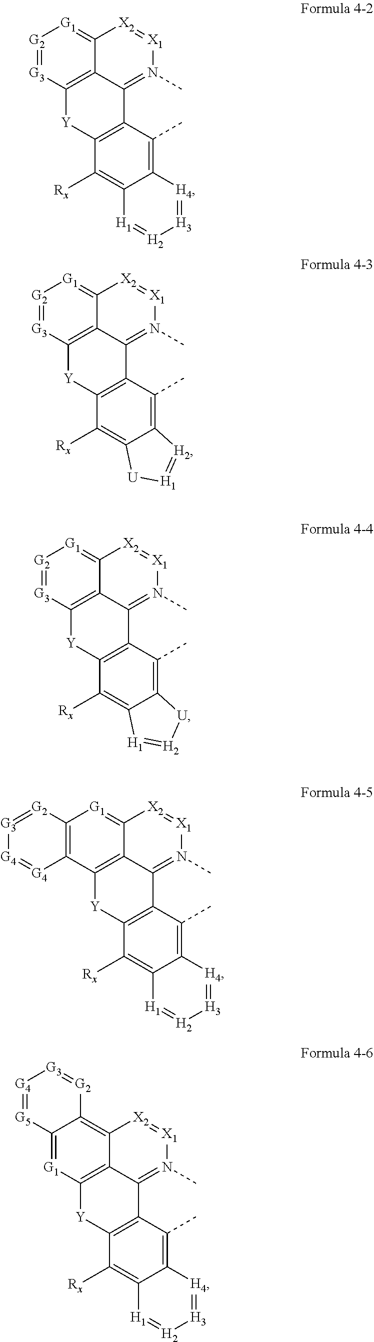 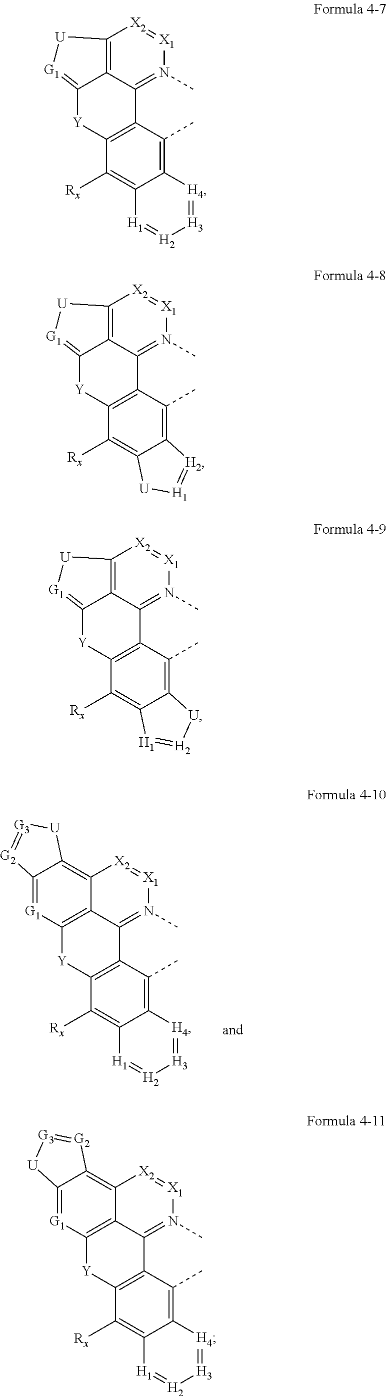
wherein
U is, at each occurrence identically or differently, selected from O, S, Se, CRᵤRᵤ, SiRᵤRᵤ, PRᵤ or NRᵤ; when two Rᵤ are present at the same time, the two Rᵤ are identical or different;
G₁ to G₅ are, at each occurrence identically or differently, selected from CR_{g} or N;
H₁ to H₄ are, at each occurrence identically or differently, selected from CRₕ or N;
Rₓ, R_{g}, Rₕ, and Rᵤ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a sulfanyl group, a sulfinyl group, a sulfonyl group, a phosphino group, and combinations thereof;
adjacent substituents Rₓ, R_{g}, Rₕ, and Rᵤ in Formula 4-2 to Formula 4-11 can be optionally joined to form a ring;
more preferably, the ligand A-B is selected from a structure represented by Formula 4-2 or Formula 4-7.

9. The metal complex of claim 7, wherein the ligand A-B is, at each occurrence, selected from the group consisting of the following structures: 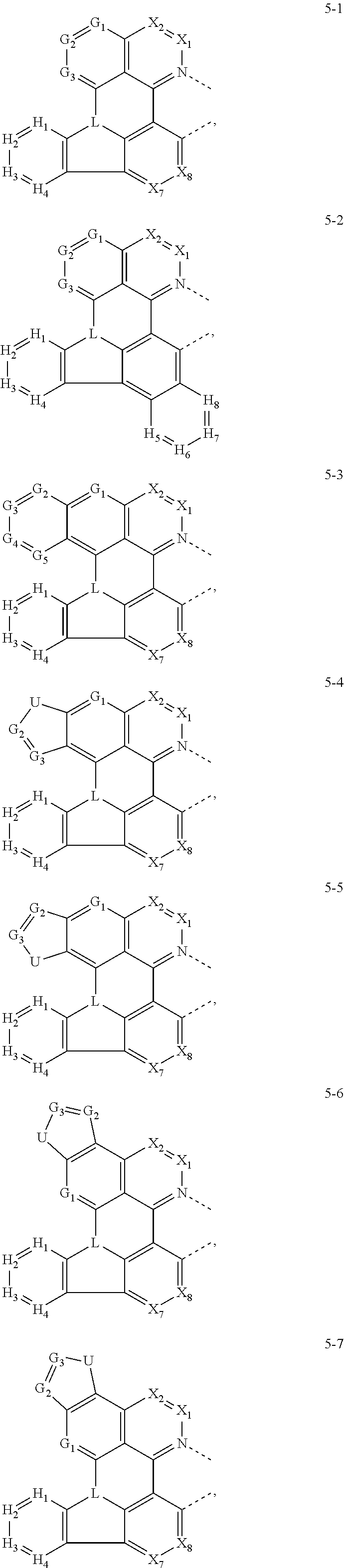 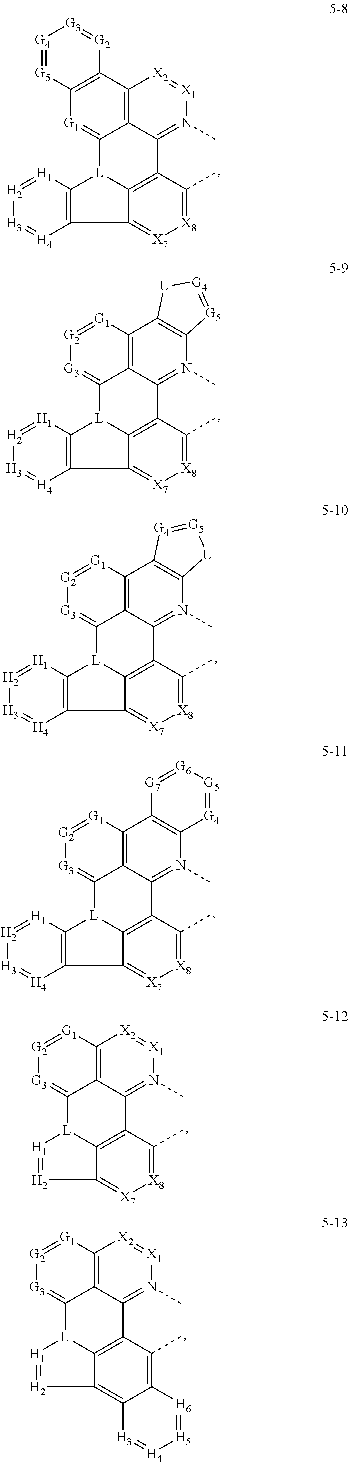 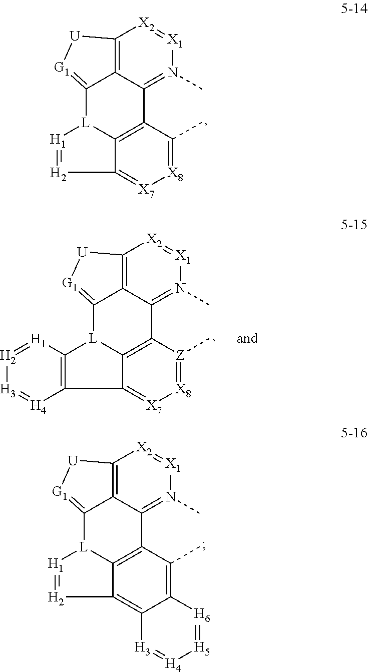
wherein
L is, at each occurrence identically or differently, selected from B, N or P;
X₁, X₂, X₇, and X₈ are, at each occurrence identically or differently, selected from N or CRₓ;
G₁ to G₇ are, at each occurrence identically or differently, selected from CR_{g} or N;
H₁ to H₈ are, at each occurrence identically or differently, selected from CRₕ or N;
U is, at each occurrence identically or differently, selected from O, S, Se, CRᵤRᵤ, SiRᵤRᵤ, PRᵤ or NRᵤ; when two Rᵤ are present at the same time, the two Rᵤ are identical or different;
Rₓ, R_{g}, Rₕ, and Rᵤ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rₓ, R_{g}, Rₕ, and Rᵤ can be optionally joined to form a ring;
preferably, the ligand A-B is selected from a structure represented by Formula 5-1, Formula 5-2, Formula 5-6, Formula 5-7, Formula 5-8 or Formula 5-11;
more preferably, the ligand A-B is selected from a structure represented by Formula 5-1, Formula 5-2 or Formula 5-11.

10. The metal complex of claim 4, wherein the ligand E-(L₁)ₐ-F is, at each occurrence, selected from the group consisting of the following structures: 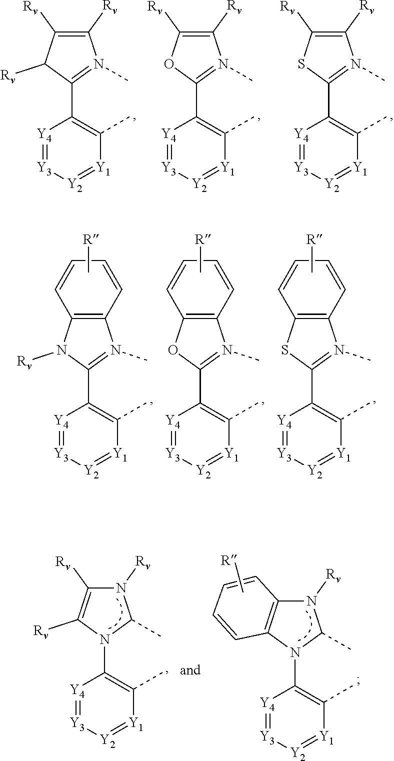
wherein
Y₁ to Y₄ are, at each occurrence identically or differently, selected from CR_{y} or N;
R″ represents, at each occurrence identically or differently, mono-substitution, multiple substitutions or non-substitution;
R″, Rᵥ, and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R″, Rᵥ, and R_{y} can be optionally joined to form a ring.

11. The metal complex of claim 4, wherein the ligand 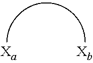
is, at each occurrence identically or differently, selected from the group consisting of Formula a to Formula m, the ligand C-D is, at each occurrence identically or differently, selected from the group consisting of Formula a to Formula h, and the ligand E-(L₁)ₐ-F is, at each occurrence identically or differently, selected from the group consisting of Formula a to Formula 1: 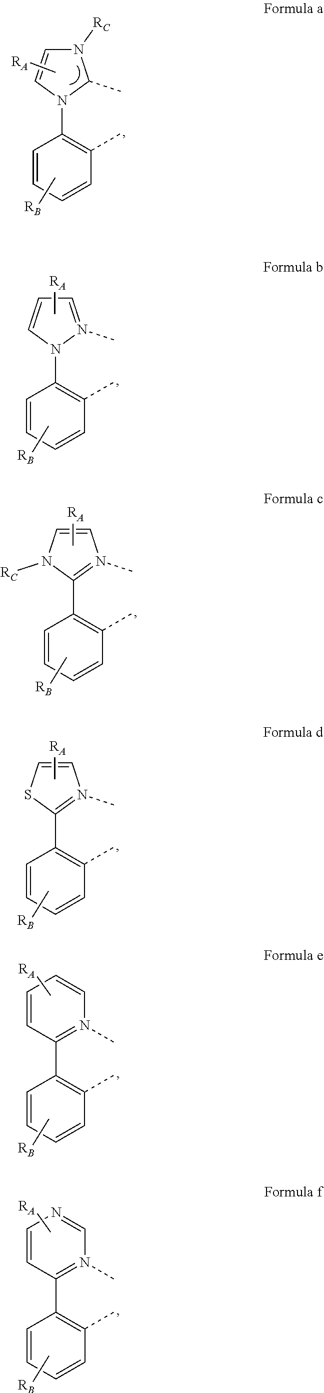 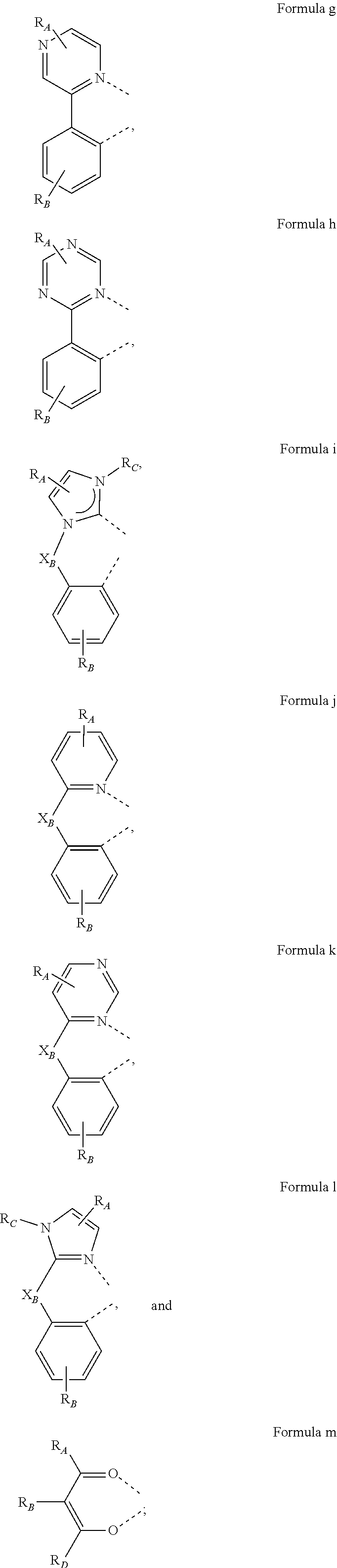
wherein
R_{A} and R_{B} represent, at each occurrence identically or differently, mono-substitution, multiple substitutions or non-substitution;
X_{B} is, at each occurrence identically or differently, selected from the group consisting of: O, S, Se, NR_{N1}, and CR_{C1}R_{C2};
R_{A}, R_{B}, R_{C}, R_{D}, R_{N1}, R_{C1}, and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R_{A}, R_{B}, R_{C}, R_{D}, R_{N1}, R_{C1}, and R_{C2} can be optionally joined to form a ring.

12. The metal complex of claim 1, wherein the metal complex has a structure represented by Formula 6, Formula 7, Formula 8 or Formula 9: 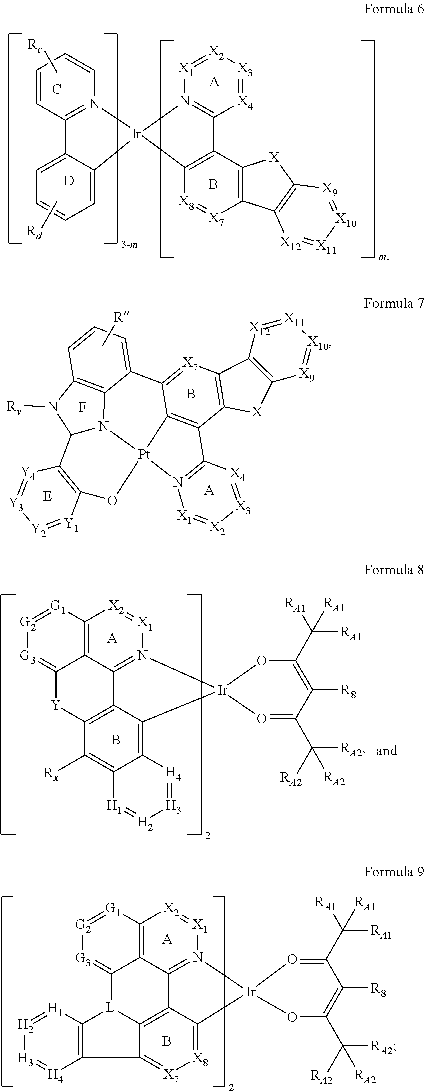
wherein
m is selected from 1, 2 or 3; when m is selected from 1, the ligand C-D is identical or different; when m is selected from 2 or 3, a plurality of the ligands A-B are identical or different; preferably, m is selected from 1;
X is selected from the group consisting of: O, S, Se, NR₂, CR₂R₂, and SiR₂R₂;
X₁ to X₄ and X₇ to X₁₂ are, at each occurrence identically or differently, selected from CRₓ or N;
Y₁ to Y₄ are, at each occurrence identically or differently, selected from CR_{y} or N;
Y is selected from SiR₃R₃, GeR₃R₃, NR₃, PR₃, O, S or Se; when two R₃ are present at the same time, the two R₃ are identical or different;
L is, at each occurrence identically or differently, selected from B, N or P;
G₁ to G₃ are, at each occurrence identically or differently, selected from CR_{g} or N;
H₁ to H₄ are, at each occurrence identically or differently, selected from CRₕ or N;
R″, R_{c}, and R_{d} represent, at each occurrence identically or differently, mono-substitution, multiple substitutions or non-substitution;
R_{A1}, R_{A2}, R_{B}, R₂, R₃, Rₓ, R_{y}, R″, R_{c}, R_{d}, R_{g}, Rₕ, and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents in Formula 6 can be optionally joined to form a ring;
adjacent substituents in Formula 7 can be optionally joined to form a ring;
adjacent substituents in Formula 8 can be optionally joined to form a ring;
adjacent substituents in Formula 9 can be optionally joined to form a ring.

13. The metal complex of claim 7, wherein X and/or Y are, at each occurrence identically or differently, selected from O or S; preferably, X and/or Y are selected from O.

14. The metal complex of claim 4, wherein Rₐ, R_{b}, R_{c}, R_{d}, Rₑ, and R_{f} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a cyano group, and combinations thereof;
preferably, at least one of Rₐ and/or R_{b} is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, a cyano group, and combinations thereof.

15. The metal complex of claim 7, wherein at least one of X₉ to X₁₂ is selected from CRₓ, and the Rₓ is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
preferably, at least one of X₉ to X₁₂ is selected from CRₓ, and the Rₓ is, at each occurrence identically or differently, substituted or unsubstituted aryl having 6 to 30 carbon atoms, substituted or unsubstituted heteroaryl having 3 to 30 carbon atoms, a cyano group, and combinations thereof;
more preferably, at least one of X₉ to X₁₂ is selected from CRₓ, and the Rₓ is a cyano group;
most preferably, X₁₀ is selected from CRₓ, and the Rₓ is a cyano group.

16. The metal complex of claim 7, wherein at least two of X₉ to X₁₂ are selected from CRₓ, and the Rₓ is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
preferably, at least two of X₉ to X₁₂ are selected from CRₓ, and the Rₓ is, at each occurrence identically or differently, selected from the group consisting of: substituted or unsubstituted aryl having 6 to 30 carbon atoms, substituted or unsubstituted heteroaryl having 3 to 30 carbon atoms, a cyano group, and combinations thereof;
more preferably, at least two of X₉ to X₁₂ are selected from CRₓ, one of the Rₓ is a cyano group, and at least another Rₓ is selected from substituted or unsubstituted aryl having 6 to 30 carbon atoms or substituted or unsubstituted heteroaryl having 3 to 30 carbon atoms;
most preferably, X₁₀ is selected from CRₓ, and the Rₓ is a cyano group; X₉ is selected from CRₓ, and the Rₓ is substituted or unsubstituted aryl having 6 to 30 carbon atoms or substituted or unsubstituted heteroaryl having 3 to 30 carbon atoms.

17. The metal complex of claim 12, wherein at least one or at least two of R_{c} and/or R_{d} is(are) selected from substituted or unsubstituted alkyl having 1 to 20 carbon atoms, substituted or unsubstituted cycloalkyl having 3 to 20 ring carbon atoms or combinations thereof; preferably, the total number of carbon atoms of all R_{c} is at least 4 and/or the total number of carbon atoms of R_{d} is at least 4.

18. The metal complex of claim 4, wherein W, L₁, L₂, and L₃ are, at each occurrence identically or differently, selected from a single bond, O, S or NR; preferably, W, L₁, L₂, and L₃ are, at each occurrence identically or differently, selected from a single bond or O.

19. The metal complex of claim 6, wherein V₁ and V₂ are both selected from CRᵥ, and two Rᵥ are joined to form an aromatic ring having 6 ring atoms or a heteroaromatic ring having 6 ring atoms; and/or V₂ and V₃ are both selected from CRᵥ, and two Rᵥ are joined to form an aromatic ring having 6 ring atoms or a heteroaromatic ring having 6 ring atoms.

20. The metal complex of claim 12, wherein X₁ to X₄ and X₇ to X₈ are, at each occurrence identically or differently, selected from CRₓ; G₁ to G₃ are, at each occurrence identically or differently, selected from CR_{g}; H₁ to H₄ are, at each occurrence identically or differently, selected from CRₕ; the Rₓ, R_{g}, and Rₕ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a cyano group, and combinations thereof;
preferably, at least two or three of the Rₓ, R_{g}, and Rₕ are, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a cyano group, and combinations thereof.

21. The metal complex of claim 12, wherein in Formula 8 and Formula 9, G₂ is CR_{g}, and/or H₃ is CRₕ, and/or in Formula 9, X₈ is CRₓ, and R_{g}, Rₕ, and Rₓ are, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a cyano group, and combinations thereof.

22. The metal complex of claim 12, wherein at least one or two of R_{A1} is(are) selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms or combinations thereof; and/or at least one of R_{A2} is substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms or combinations thereof;
preferably, at least two of R_{A1} are selected from substituted or unsubstituted alkyl having 2 to 20 carbon atoms, substituted or unsubstituted cycloalkyl having 3 to 20 ring carbon atoms, substituted or unsubstituted heteroalkyl having 2 to 20 carbon atoms or combinations thereof; and/or at least two of R_{A2} are selected from substituted or unsubstituted alkyl having 2 to 20 carbon atoms, substituted or unsubstituted cycloalkyl having 3 to 20 ring carbon atoms, substituted or unsubstituted heteroalkyl having 2 to 20 carbon atoms or combinations thereof.

23. The metal complex of claim 1, wherein the metal complex is, at each occurrence identically or differently, selected from any one of the group consisting of:

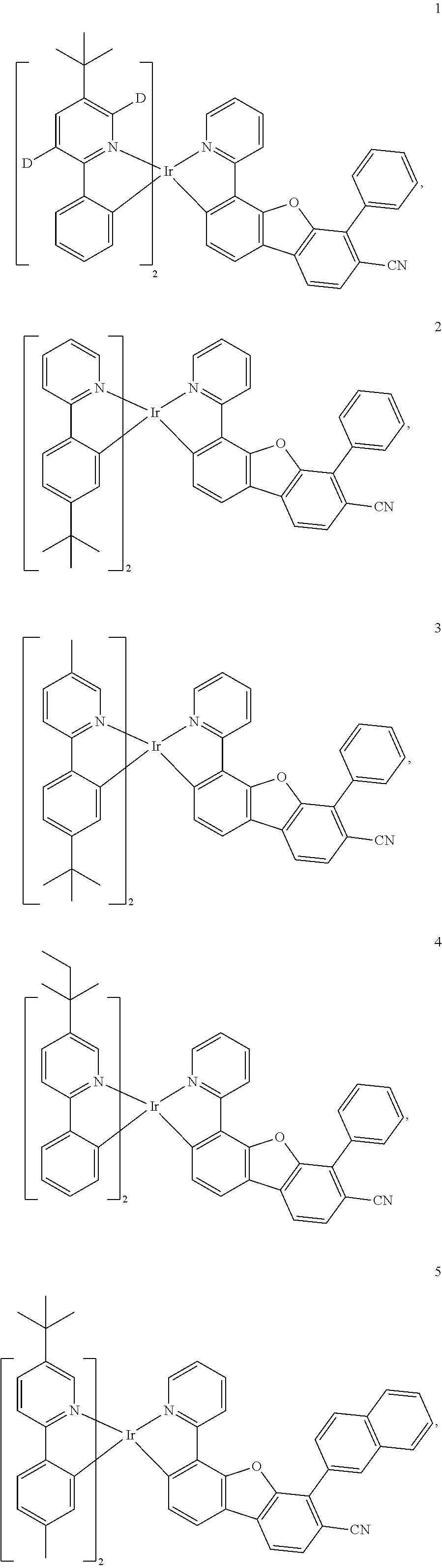

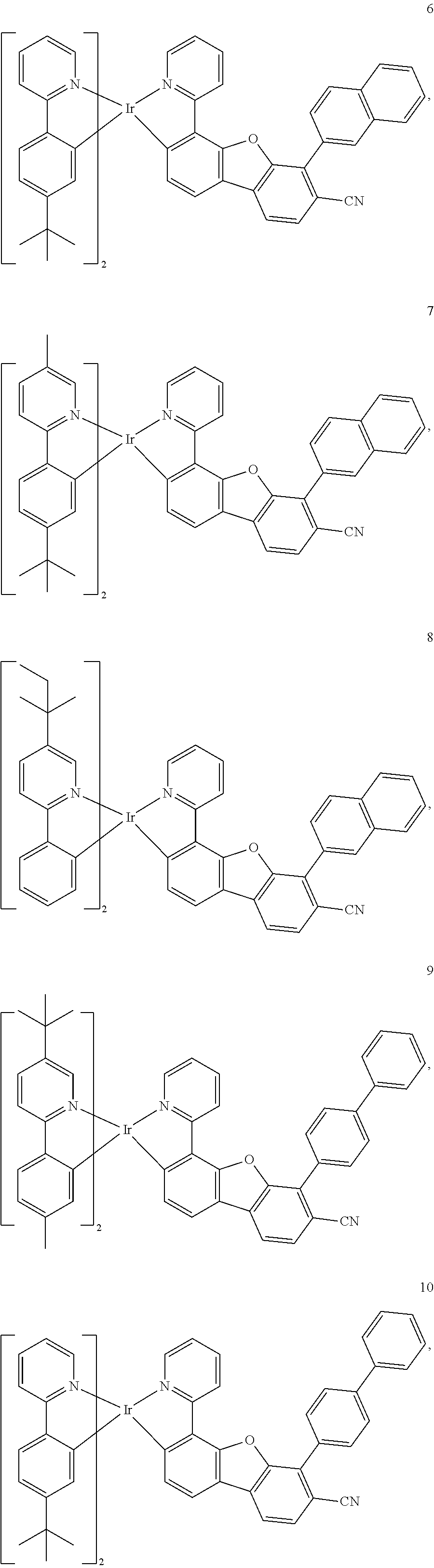

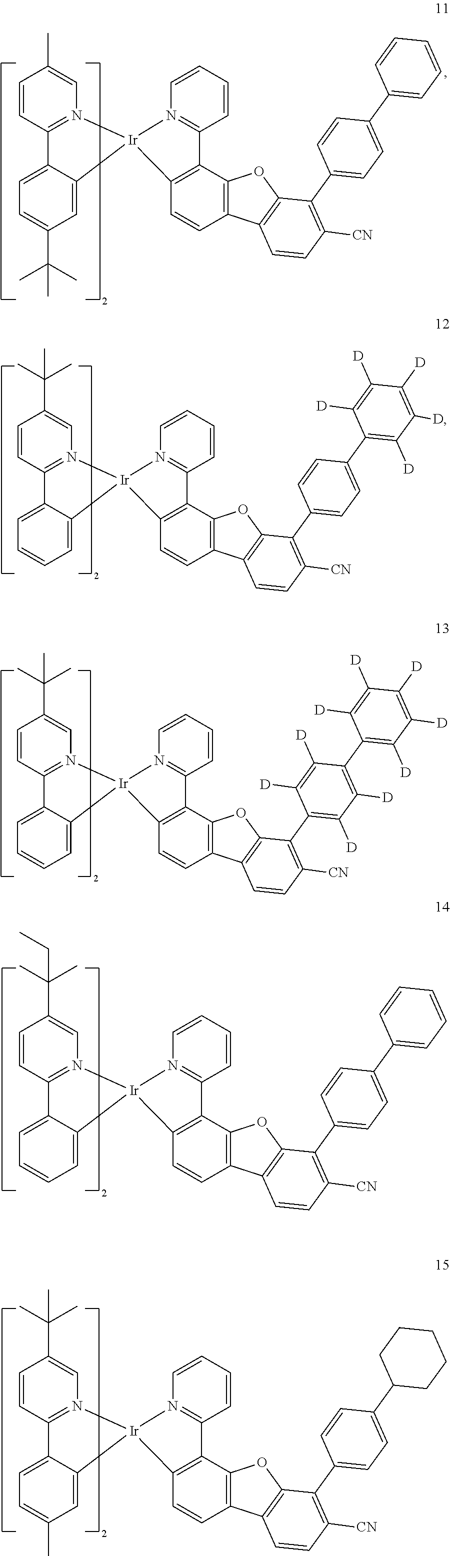

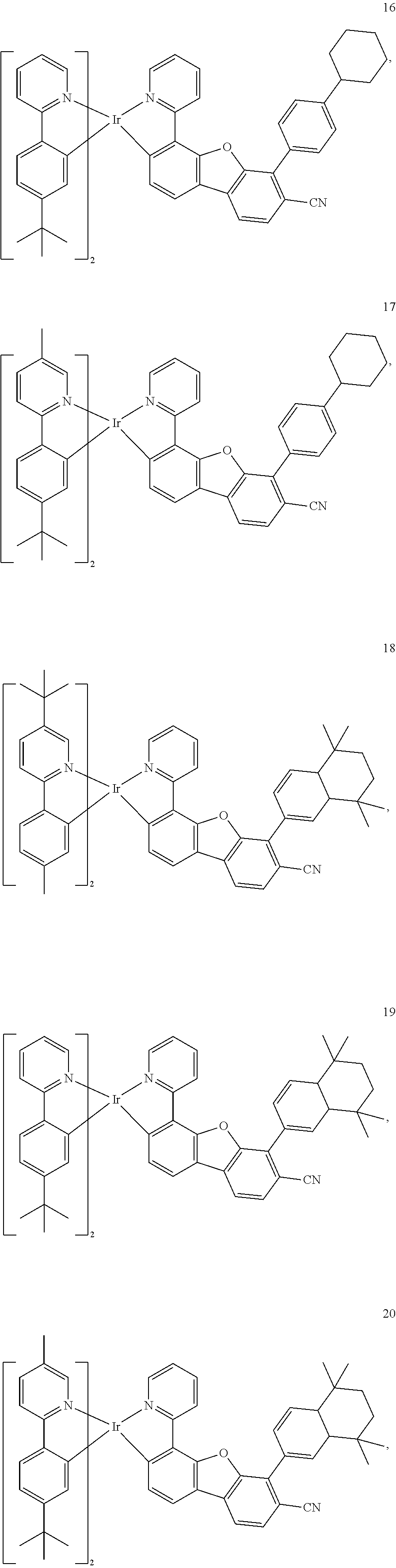

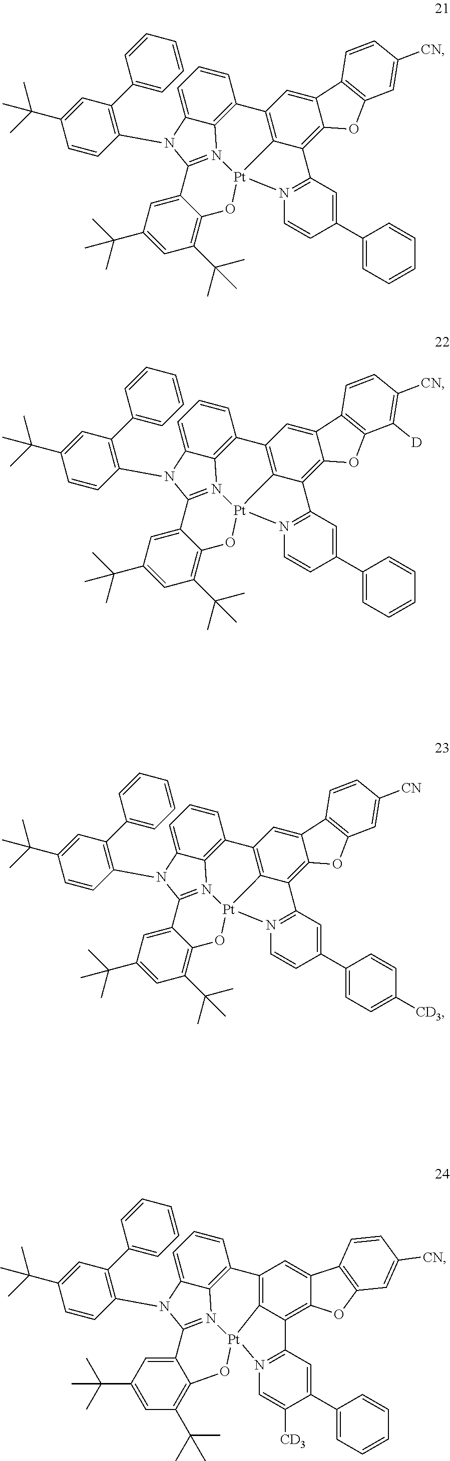

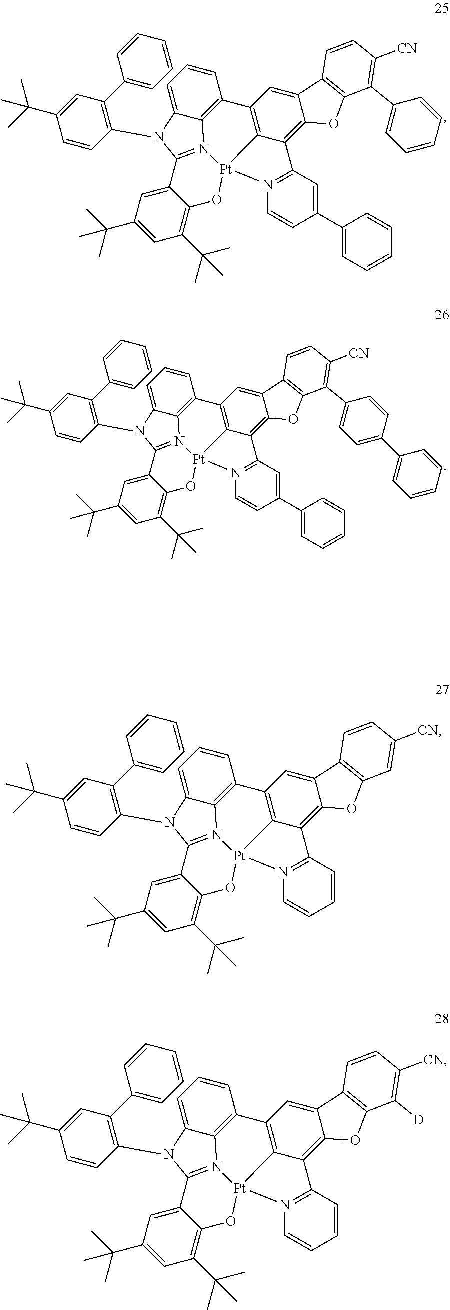

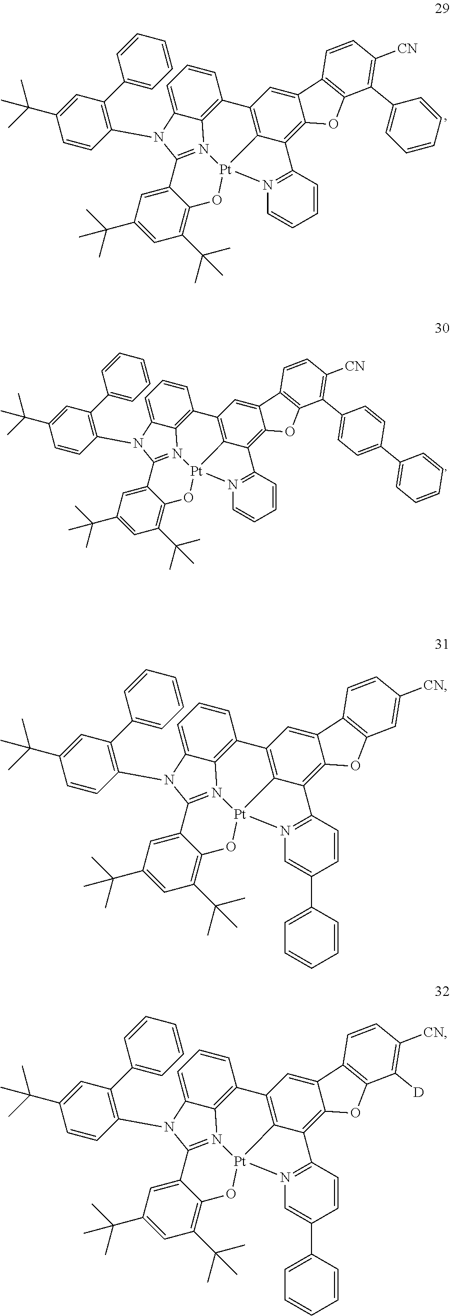

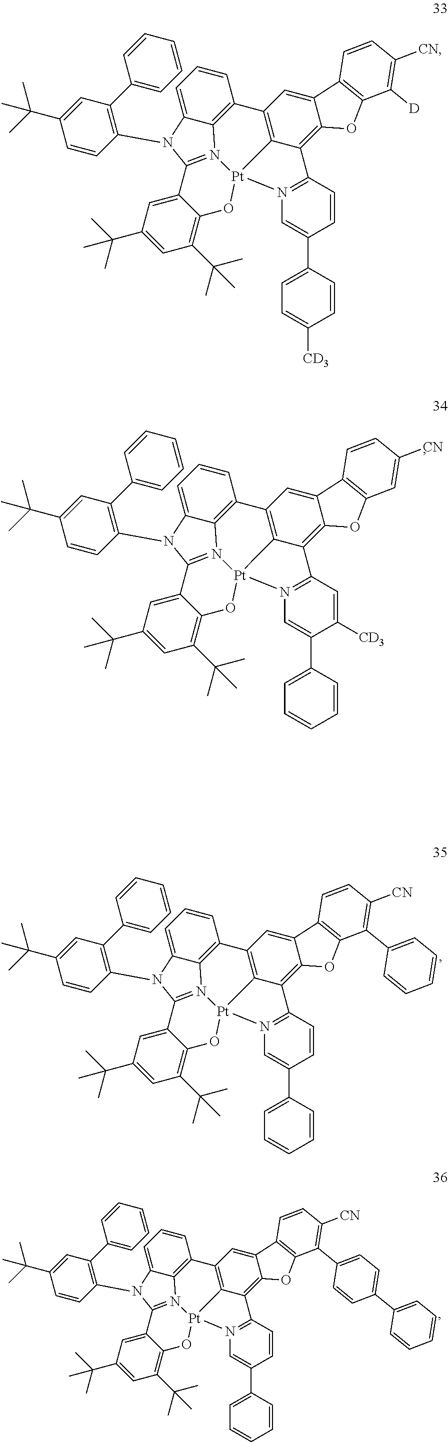

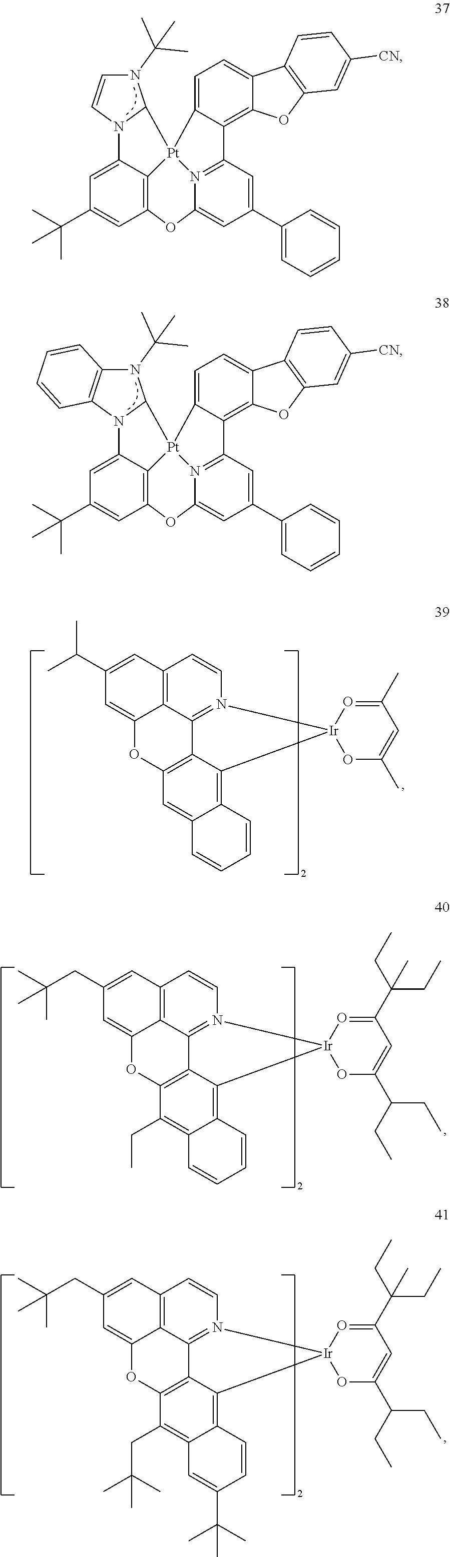

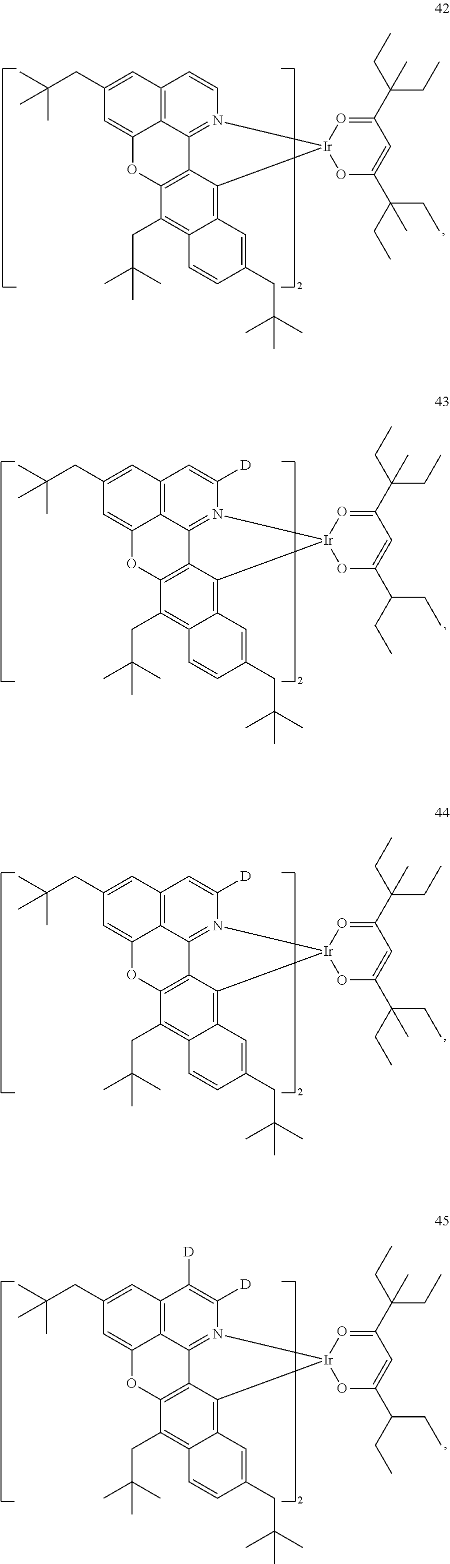

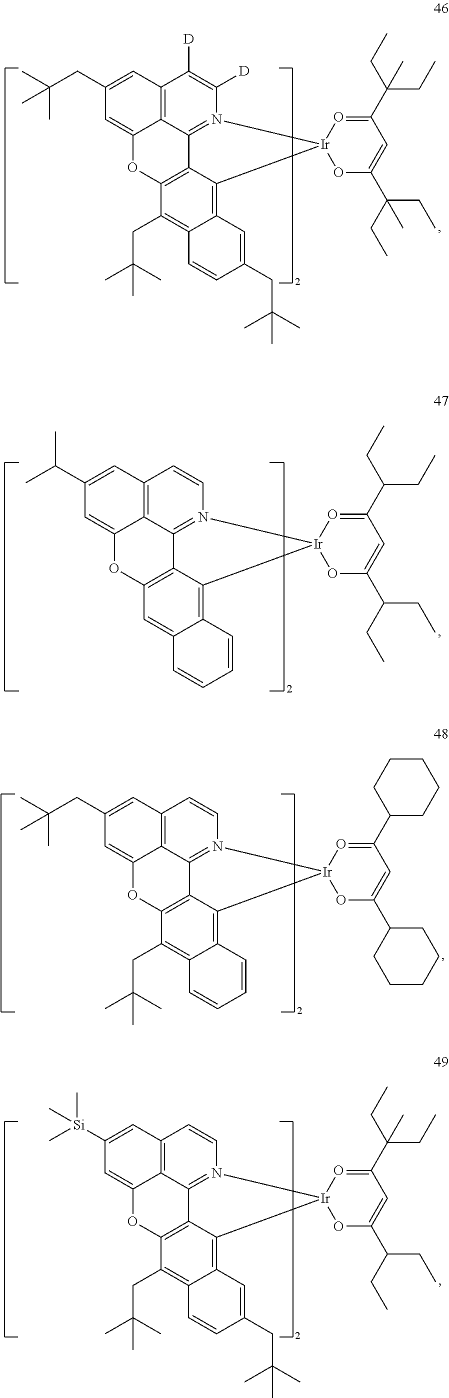

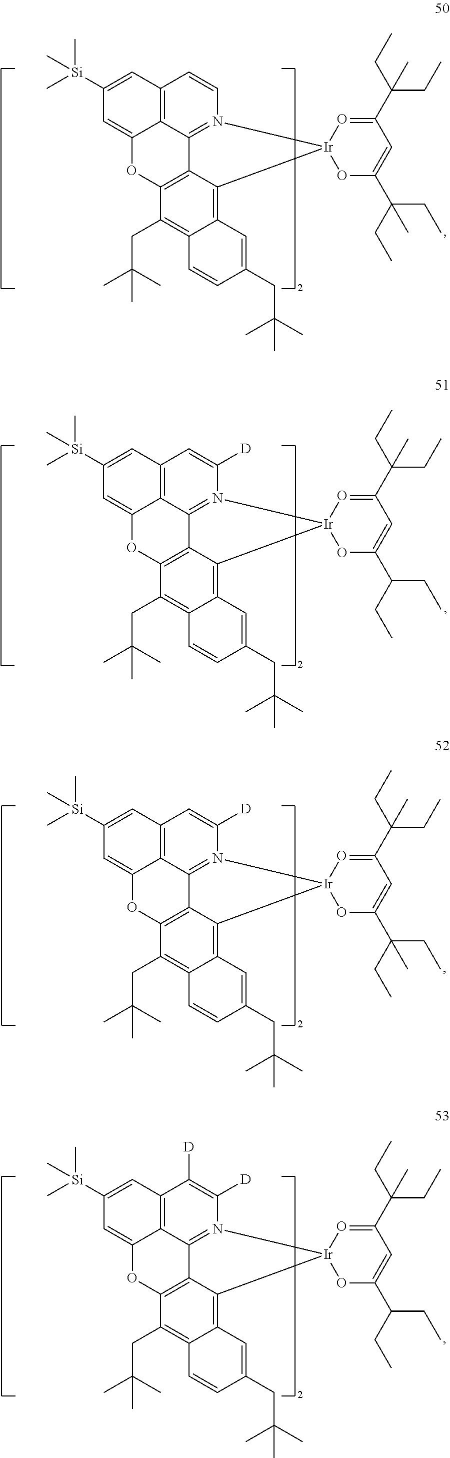

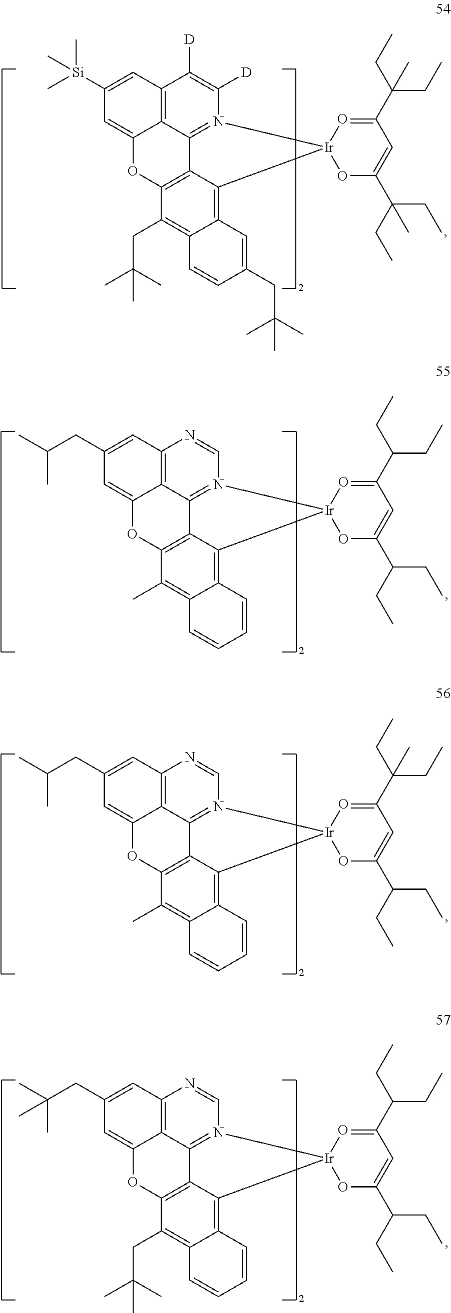

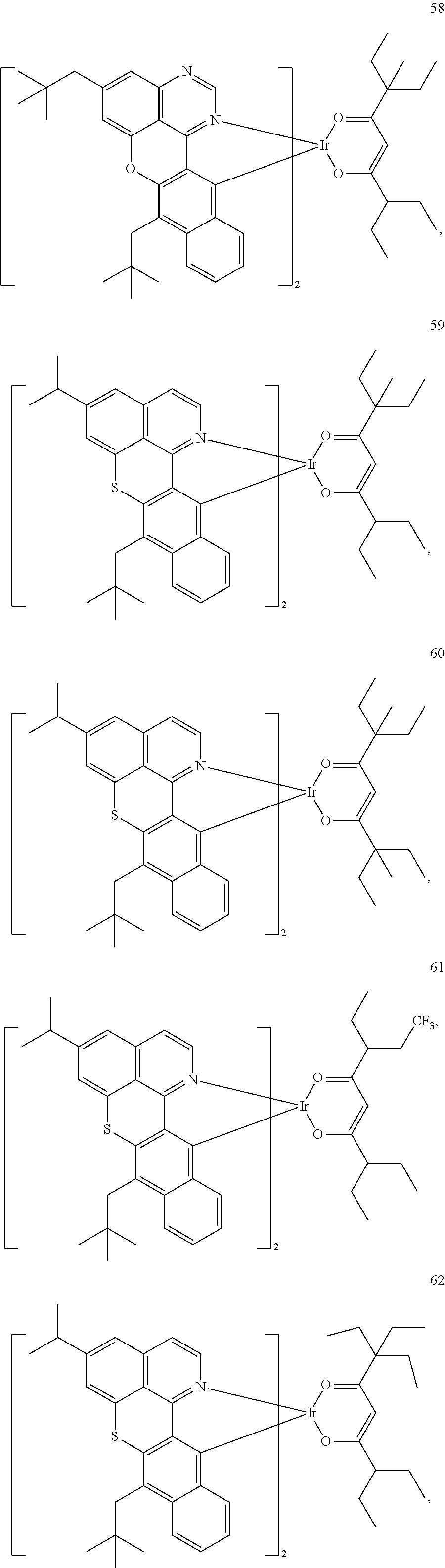

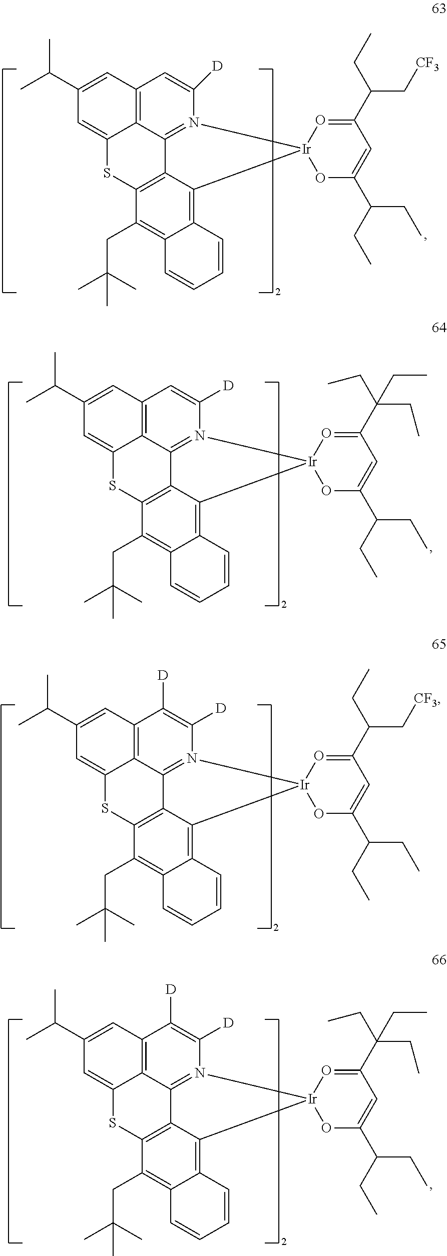

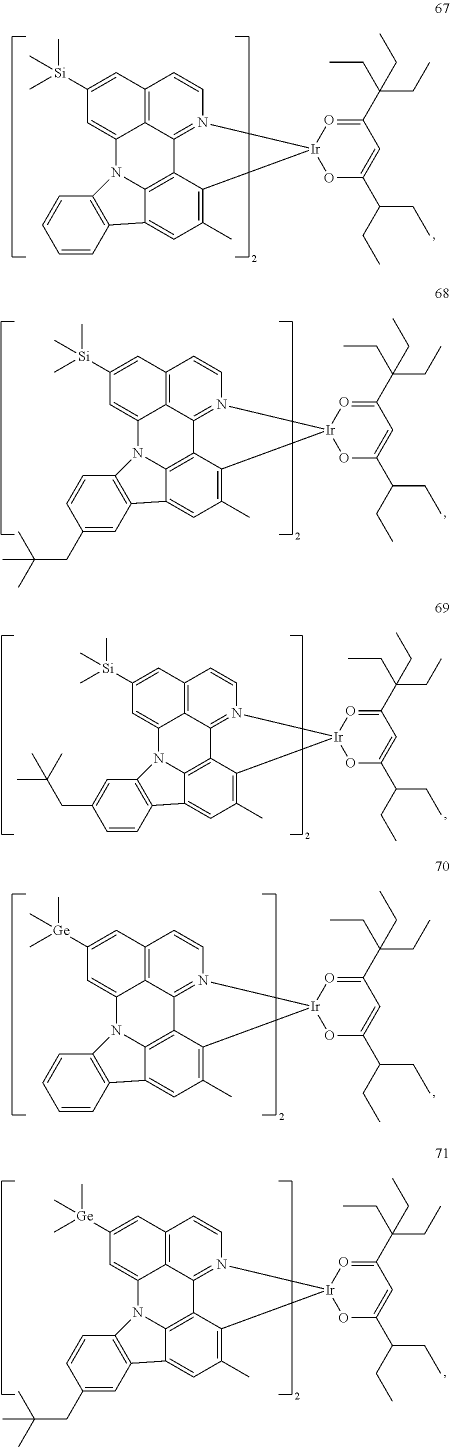

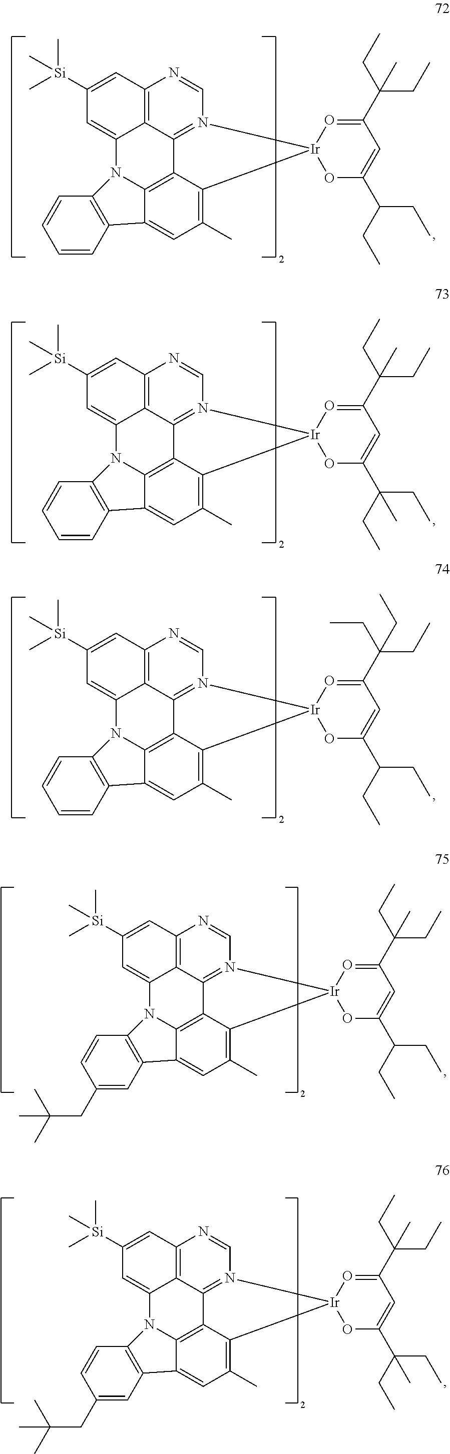

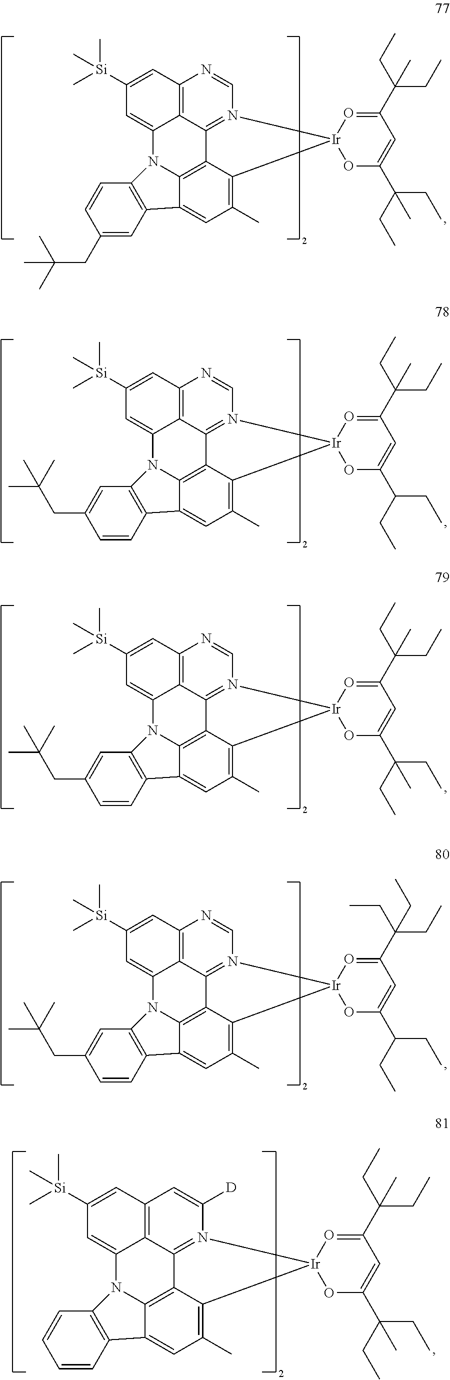

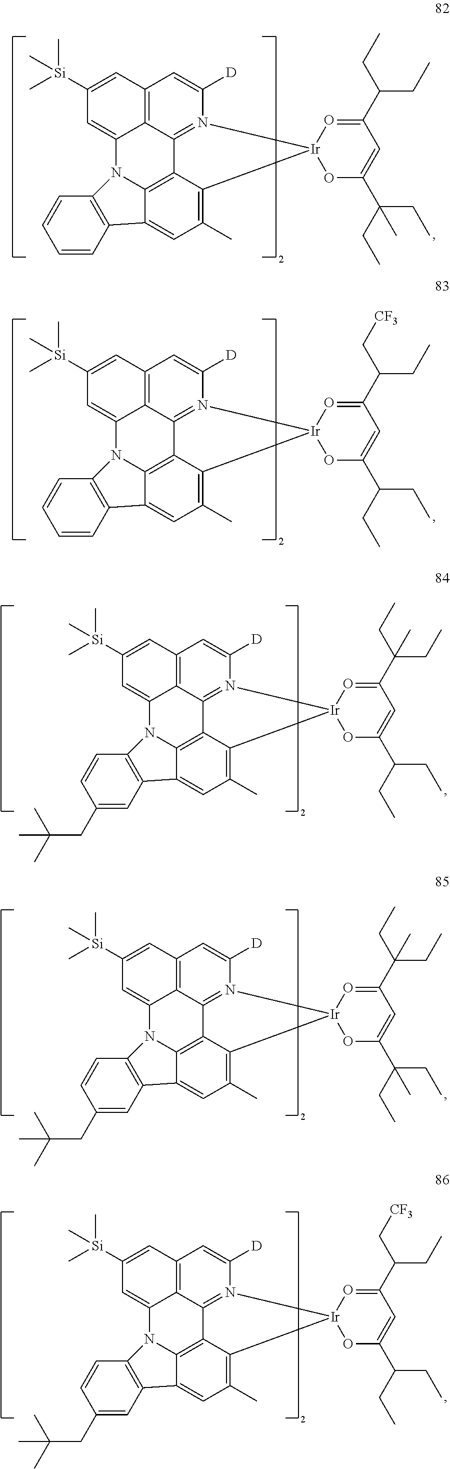

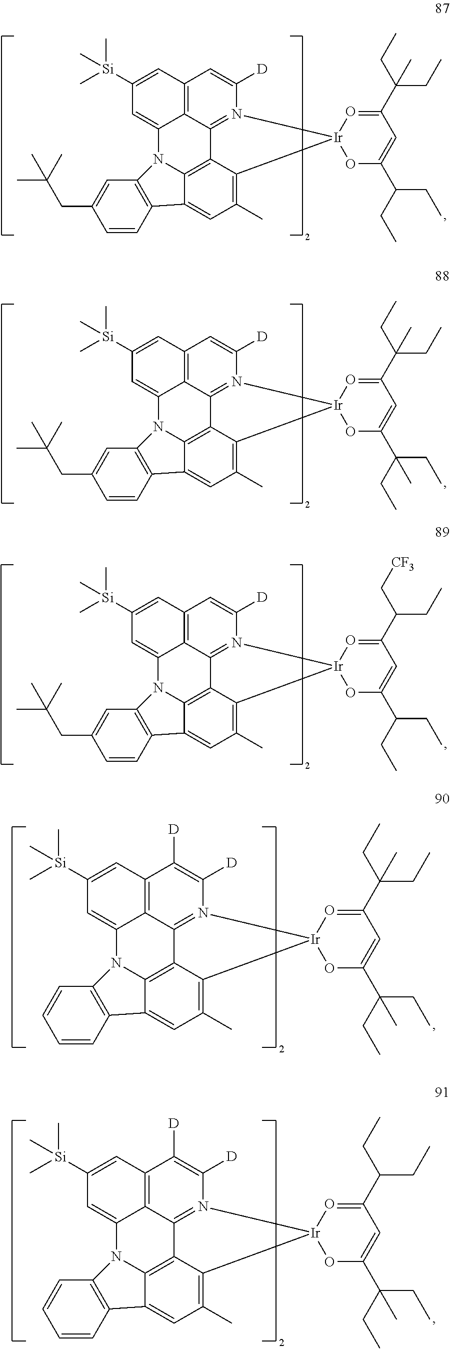

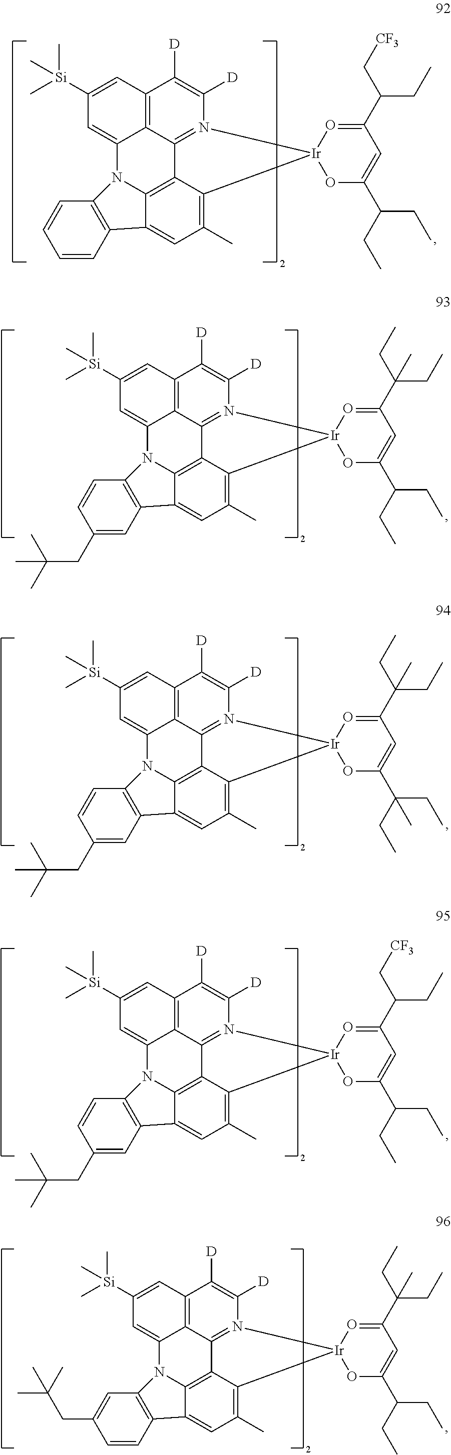

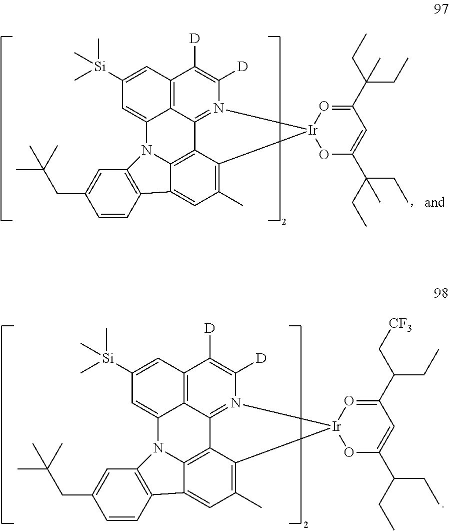

24. An electroluminescent device, comprising:
an anode,
a cathode, and
an organic layer disposed between the anode and the cathode, wherein at least one layer of the organic layer comprises the metal complex of claim 1.

25. The electroluminescent device of claim 24, wherein the organic layer comprising the metal complex is an emissive layer.

26. The electroluminescent device of claim 25, wherein the emissive layer further comprises at least one first host compound;
preferably, the emissive layer comprises at least two host compounds;
more preferably, at least one of the host compounds comprises at least one chemical group selected from the group consisting of: benzene, pyridine, pyrimidine, triazine, carbazole, azacarbazole, indolocarbazole, dibenzothiophene, azadibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene, and combinations thereof.

27. The electroluminescent device of claim 24, wherein the electroluminescent device is a bottom-emitting device, and EQE is greater than or equal to 25% at a current of 1000 cd/m²;
preferably, the electroluminescent device is a bottom-emitting device, and the EQE of the electroluminescent device is greater than or equal to 26% at a current of 1000 cd/m²;
more preferably, the electroluminescent device is a bottom-emitting device, and the EQE of the electroluminescent device is greater than or equal to 27% at a current of 1000 cd/m².

28. The electroluminescent device of claim 24, wherein the electroluminescent device is a top-emitting device, and EQE is greater than or equal to 40% at a current of 1000 cd/m²;
preferably, the electroluminescent device is a top-emitting device, and the EQE of the electroluminescent device is greater than or equal to 45% at a current of 1000 cd/m²;
more preferably, the electroluminescent device is a top-emitting device, and the EQE of the electroluminescent device is greater than or equal to 50% at a current of 1000 cd/m².

29. A compound composition, comprising the metal complex of claim 1.
